(19) United States
(12) Patent Application Publication
(10) Pub. No.: US 2016/0269026 A1
(43) Pub. Date: Sep. 15, 2016

(54) SEMICONDUCTOR DEVICE

(71) Applicant: Renesas Electronics Corporation, Tokyo (JP)

(72) Inventors: Toru MOCHIDA, Tokyo (JP); Wataru UCHIDA, Tokyo (JP); Kentaro KAWAHARA, Tokyo (JP)

(21) Appl. No.: 14/964,395

(22) Filed: Dec. 9, 2015

(30) Foreign Application Priority Data
Mar. 13, 2015 (JP) 2015-050262

(51) Int. Cl. H03K 19/00; G01R 31/319; H03K 3/356

(52) U.S. Cl. CPC H03K 19/0008; H03K 3/356; G01R 31/31922

(57) ABSTRACT

The present invention provides a semiconductor device which is easily tested. A semiconductor device includes an input signal to which an operation clock signal is supplied, a process unit having a plurality of F/F circuits synchronized with the operation clock signal, output terminals to which an output signal of the process unit is transmitted, output-stage F/F circuits coupled between the process unit and the output terminals, an input terminal to which a test signal is supplied, an input terminal to which a test clock signal is supplied, an output terminal to which the test clock signal is transmitted via a signal line, and first selection circuits selecting a clock signal with which the output-stage F/F circuit is synchronized and an input of the output-stage F/F circuit.

### CROSS-REFERENCE TO RELATED APPLICATIONS

The disclosure of Japanese Patent Application No. 2015-050262 filed on Mar. 13, 2015 including the specification, drawings and abstract is incorporated herein by reference in its entirety.

### BACKGROUND

The present invention relates to a semiconductor device and, more particularly, relates to a semiconductor device having a plurality of flip flop circuits.

After various tests are executed, a semiconductor device is shipped. One of the tests is an operation timing test of testing operation timings of external terminals (an external input terminal and an external output terminal or an external input/output terminal) of a semiconductor device. In the operation timing test, for example, whether delay time of an output signal which is output from an external output terminal satisfies a specification or not is examined.

Patent Literature 1 describes a technique of making timings of output signals of semiconductor devices of the same kind become the same.

### RELATED ART LITERATURE

### Patent Literature

Patent Literature 1: Japanese Unexamined Patent Application Publication No. 2001-217391

### SUMMARY

Examples of tests executed on a semiconductor device include a function test and a scan test. The function test is a test of mainly examining whether various functions provided for a semiconductor device operate normally or not. The scan test is a test of mainly examining whether wire connection in a semiconductor device is correct or not.

The operation timing test is included in the function test. To execute the function test including the operation timing test, a test pattern is formed in advance. For example, by storing a program for generating the formed test pattern in a semiconductor device and operating the semiconductor device, for example, by comparing an output signal which is output with an expectation value, whether various functions including a timing such as delay time operate properly or not can be examined. In this case, to examine whether the various functions operate properly, a test pattern which can grasp operation specifications of the various functions and determine whether the various functions operate properly or not has to be formed.

The inventors of the present invention examined and found there is a case that test time required for an operation timing test reaches about 50% of test time required for a function test. Similarly, there is a case that time required to forma test pattern for an operation timing test reaches about 50% of time required to form a test pattern for a function test. The reason is that, also in the case of forming a test pattern for an operation timing test, a pattern which can grasp the operation specifications of various functions and determine whether delay time of an output signal or an input signal from an external terminal satisfies the specification or not has to be formed, and a program capable of forming the pattern in a semiconductor device has to be generated.

On the other hand, in the operation timing test, as described as an example, whether delay time of an output signal satisfies a specification or not is examined. When a semiconductor device executing a test operates synchronously with an operation clock signal, by providing the semiconductor device with an external terminal outputting a clock signal synchronized with the operation clock signal, delay time of an output signal can be examined on the basis of the cock signal output from the external terminal. However, as the scale of the semiconductor device increases, timing design in the semiconductor device is becoming difficult. That is, a semiconductor device has a logic circuit and a plurality of flip flop circuits (hereinbelow, also called F/F circuits). As the scale becomes larger, the number of F/F circuits becomes enormous, and it is becoming difficult to make the F/F circuits synchronized. Consequently, it is becoming difficult to obtain the operation clock signal synchronized with the F/F circuits and to output a clock signal synchronized with the operation clock signal from the external terminal.

In Patent Literature 1, although it is described that timings of output signals are set to the same in advance in semiconductor devices of the same kind, a test pattern for an operation timing test is not recognized.

The other problems and novel features will become apparent from the description of the specification and the appended drawings.

In an embodiment, a semiconductor device includes: a first external terminal to which an operation clock signal is supplied; a process unit including a logic circuit and a plurality of F/F circuits each operating synchronously with the operation clock signal; and a second external terminal to which an output signal generated by the process unit is transmitted. The semiconductor device also has: an output-stage F/F circuit coupled between the process unit and the second external terminal; a third external terminal to which a test signal is supplied; a fourth external terminal to which a test clock signal is supplied; and a fifth external terminal to which the test clock signal is transmitted via a signal line. The semiconductor device also has a first selection circuit selecting a clock signal with which the output-stage F/F circuit is synchronized and an input of the output-stage F/F circuit. At the time of transmitting an output signal generated by the process unit to the second external terminal, the first selection circuit inputs the output signal to the output-stage F/F circuit and supplies the operation clock signal as a sync clock signal. At the time of a test, the first selection circuit inputs the test signal to the output-stage F/F circuit and supplies the test clock signal as a sync clock signal.

At the time of a test, by the first selection circuit, a test signal is input to the output-stage F/F circuit. The output-stage F/F circuit operates synchronously with the test clock signal. Consequently, by examining delay time between the test signal transmitted to the second external terminal and the test clock signal transmitted to the fifth external terminal, an operation timing test of a semiconductor device can be easily executed.

In another embodiment, a semiconductor device has: a first external terminal to which an operation clock signal is supplied; a second external terminal to which an input signal is supplied; and a process unit including a logic circuit and a plurality of F/F circuits each operating synchronously with the operation clock signal. The semiconductor device also has: a third external terminal to which a test clock signal is supplied; an input-stage F/F circuit coupled between the second external terminal and the process unit; and a fourth external terminal to which an output of the input-stage F/F circuit is transmitted. The semiconductor device further has a first selection circuit selecting a clock signal with which the input-stage F/F circuit is synchronized. When the process unit processes an input signal, the first selection circuit selects the operation clock signal as a sync clock signal of the input-stage F/F circuit. At the time of a test, the first selection circuit selects the test clock signal as a sync clock signal of the input-stage F/F circuit.

At the time of a test, the first selection circuit selects a test clock signal as a sync clock signal of the input-stage F/F circuit. Consequently, the input-stage F/F circuit fetches a signal according to the input signal synchronously with the test clock signal. By examining an output of the input-stage F/F circuit transmitted to the fourth external terminal, whether a signal according to an input signal supplied to the second external terminal is fetched in the input-stage F/F circuit synchronously with the test clock signal can be easily determined.

Further, in another embodiment, a semiconductor device includes: a first external terminal to which an operation clock signal is supplied; a second external terminal to which a test clock signal is supplied; and a process unit including a logic circuit and a plurality of flip flop circuits each operating synchronously with the operation clock signal, and generating a first output signal and a second output signal. The semiconductor device also has: third and fourth external terminals, when the process unit generates the first and second output signals, to which the first and second output signals are transmitted; a first output-stage F/F circuit coupled between the process unit and the third external terminal; and a second output-stage F/F circuit coupled between the process unit and the fourth external terminal. Moreover, the semiconductor device has a first selection circuit coupled to the first output-stage F/F circuit and selecting a sync clock with which the first output-stage F/F circuit is synchronized and an input of the first output-stage F/F circuit; and a second selection circuit coupled to the second output-stage F/F circuit and selecting a sync clock with which the second output-stage F/F circuit is synchronized and an input of the second output-stage F/F circuit.

When the process unit generates the first and second output signals, the first and second selection circuits select the operation clock as the sync clock signal and select the first and second output signals as inputs of the first and second output-stage F/F circuits. At the time of a test, the first and second selection circuits select the test clock signal as the sync clock signal and select outputs of the first and second output-stage F/F circuits as inputs of the first and second output-stage flip flop circuits so that the outputs of the first and second output-stage F/F circuits change synchronously with the test clock signal.

At the time of a test, the first and second selection circuits control so that the first and second output-stage F/F circuits generate outputs which change synchronously with the test clock signal. Consequently, by examining the time difference between an output of the first output-stage F/F circuit transmitted to the third external terminal and an output of the second output-stage F/F circuit transmitted to the fourth external terminal, the operation timing test can be easily executed. In the embodiment, at the time of a test, the first and second output-stage F/F circuits generate a test signal (test pattern) whose logic value (“1”, “0”) is inverted synchronously with the test clock signal. Therefore, at the time of a test, a test signal may not be supplied to the semiconductor device.

According to the embodiment, a semiconductor device which can be easily tested can be provided.

### BRIEF DESCRIPTION OF THE DRAWINGS

FIG. 1 is a block diagram illustrating the configuration of a semiconductor device according to a first embodiment.

FIG. 2 is a block diagram illustrating the configuration of an output system of the semiconductor device according to the first embodiment.

FIG. 3 is a block diagram illustrating the configuration of an output-stage test circuit, an output-stage F/F circuit, an input-stage test circuit, and an input-stage F/F circuit according to the first embodiment.

FIG. 4 is a block diagram illustrating the configuration of an input system of the semiconductor device according to the first embodiment.

FIG. 5 is a flowchart diagram illustrating operations of the semiconductor device according to the first embodiment.

FIG. 6 is a flowchart diagram illustrating operations of the semiconductor device according to the first embodiment.

FIG. 7 is a block diagram illustrating the configuration of an output-stage test circuit, an output-stage F/F circuit, an input-stage test circuit, and an input-stage F/F circuit according to a modification of the first embodiment.

FIG. 8 is a waveform chart illustrating operations ((A) to (E)) of a semiconductor device according to a second embodiment.

FIG. 9 is a waveform chart illustrating operations ((A) to (F)) of the semiconductor device according to the second embodiment .

FIG. 10 is a waveform chart illustrating operations ((A) to (G)) of the semiconductor device according to the second embodiment.

FIG. 11 is a block diagram illustrating the configuration of a semiconductor device according to a third embodiment.

FIG. 12 is a block diagram illustrating the configuration of an output-stage test circuit and an output-stage F/F circuit according to the third embodiment.

FIG. 13 is a waveform chart for explaining the operations ((A) to (D)) according to the third embodiment.

FIG. 14 is a block diagram illustrating the configuration of a test circuit according to a first modification of the third embodiment.

FIG. 15 is a waveform chart for explaining the operations of the first modification of the third embodiment.

FIG. 16 is a block diagram illustrating the configuration of a test circuit according to a second modification of the third embodiment.

FIG. 17 is a waveform chart for explaining operations ((A) and (B)) of the second modification of the third embodiment.

### DETAILED DESCRIPTION

Hereinbelow, embodiments of the present invention will be described with reference to the drawings. In all of the diagrams for explaining the embodiments, as a rule, the same reference numeral is designated to the same part and its repetitive description will not be repeated.

To provide a semiconductor device which can be easily tested, the inventors of the present invention came to reach an idea of dividing the function tests into the operation timing test and the other tests. Specifically, a semiconductor device is divided into a process unit achieving functions of the semiconductor device and an input/output circuit coupling the process unit and an external terminal of the semiconductor device. The operation timing test is executed on the divided input/output circuit, and the function test is executed on the process unit. In this case, the function test executed on the process unit is formed by grasping the function operations achieved by the process unit. In such a manner, the test pattern used for the operation timing test can be formed without grasping the functions achieved by the process unit.

The functions achieved by the process unit are determined by, for example, the user of the semiconductor device. In other words, the functions achieved by the process unit vary among semiconductor devices. Even the functions achieved by the process unit vary as described above, the test pattern for the operation timing test can be generated even when the functions of the process units are not grasped. Consequently, the time required for the operation timing test can be shortened.

In embodiments to be described hereinbelow, the case where the process unit has a microcontroller (hereinbelow, also called a processor) will be described as an example. In this case, a test pattern for a function test to the process unit is achieved when the processor in the process unit executes a program. That is, a program generating a test pattern has to be generated. In contrast, a test pattern for an operation timing test is supplied from a tester provided on the outside of the semiconductor device to the semiconductor device. Consequently, even when the configuration in the process unit changes, the operation timing test can be executed.

### First Embodiment

### General Configuration of Semiconductor Device

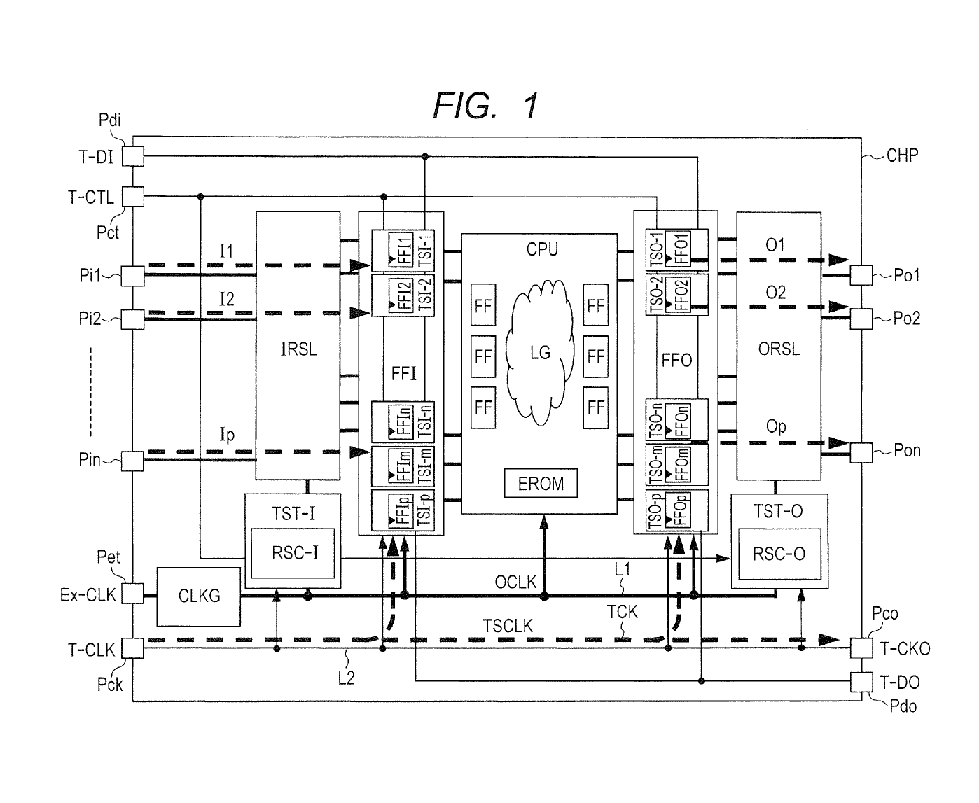

First, the general configuration of a semiconductor device will be described with reference to FIG. 1. FIG. 1 is a block diagram illustrating the configuration of a semiconductor device. In FIG. 1, CHP expresses a semiconductor device. The semiconductor device CHP has a semiconductor chip and a package in which the semiconductor chip is sealed. In the semiconductor chip, a plurality of circuit blocks are formed by a known semiconductor manufacturing technique. The semiconductor chip is sealed in a package. In FIG. 1, the circuit blocks are illustrated as boxes. The package is provided with a plurality of external terminals, and the external terminals and the circuit blocks formed in the semiconductor chip are electrically coupled via wires or the like. Although the semiconductor device CHP has the external terminals as described above, in FIG. 1, only input external terminals (hereinbelow, also called input terminals) Pdi, Pct, Pet, Pck, and Pi1 to Pin and output external terminals (hereinbelow, also called output terminals) Pco, Pdo, and Pd1 to Pon are illustrated. Although an example that one semiconductor chip is sealed in a package is illustrated, obviously, a plurality of semiconductor chips maybe sealed in a single package.

The input terminal Pet is an external terminal to which an external operation clock signal (hereinbelow, also simply called operation clock signal) Ex-CLK for operating the semiconductor device CHIP is supplied, and the input terminals Pdi, Pct, and Pck and the output terminals Pco and Pdo are external terminals used at the time of a test. Specifically, the input terminal Pdi is an external terminal to which a test signal T-DI is supplied, and the input terminal Pct is an input terminal to which an external test control signal (hereinbelow, also simply called a test control signal) T-CTL is supplied. The input terminal Pck is an external terminal to which an external test clock signal (hereinbelow, also simply called a test clock signal) T-CLK is supplied, and the output terminal Pco is an external terminal to which the test clock signal T-CLK is transmitted and which outputs the transmitted test clock signal T-CLK as an external test clock signal (hereinbelow, also simply called a test clock signal) T-CKO. The output terminal Pdo is an external terminal outputting an output signal T-DO.

In FIG. 1, CPU expresses a processor. In the specification, the case where a process unit determining the functions of the semiconductor device CHP by the user is the processor CPU will be described. However, the invention is not obviously limited to the case. The processor CPU has a memory EROM storing a program, a logic circuit LG, and a plurality of F/F circuits FF. By the logic circuit LG and the F/F circuits FF, a process circuit executing a process according to a program stored in the memory EROM is configured. In the embodiment, each of the F/F circuits FF operates synchronously with an internal operation clock signal OCLK. That is, the processor CPU operates synchronously with the internal operation clock signal OCLK. The memory EROM may be a volatile memory or an electrically-rewritable nonvolatile memory.

In the diagram, FFI denotes an input-first-stage F/F circuit, and FFO denotes an output-final-stage F/F circuit. The input-first-stage F/F circuit FFI has a plurality of input-stage F/F circuits FFI1 to FFIp and input-stage test circuits TSI-1 to TSI-p. Each of the input-stage F/F circuits FFI1 to FFIp may be comprised of a single input F/F circuit or by a plurality of input F/F circuits. The input-stage F/F circuits FFI1 to FFIp correspond to the input-stage test circuits TSI-1 to TSI-p on a one-to-one basis. Although not limited, in the first embodiment, the input F/F circuits configuring the input-stage F/F circuits FFI1 to FFIp have the same configuration, and the input-stage test circuits TSI-1 to TSI-p also have similar configurations.

Each of the input-stage test circuits TSI-1 to TSI-p is controlled by the external test control signal T-CTL and the test signal T-DI supplied via the input terminals Pct and Pdi. Specifically, in an operation timing test, an input-stage F/F circuit designated by the external test control signal T-CTL and the test signal T-DI is selected from the input-stage F/F circuits FFI1 to FFIp included in the input-first-stage F/F circuit FFI, and the internal test clock signal TSCLK is supplied as a sync clock signal to the selected input-stage F/F circuit. In a normal operation in which the processor CPU as the process unit operates, the same internal operation clock signal OCLK as that in the processor CPU is supplied as a sync clock signal to the input-stage F/F circuit.

For example, the input-stage F/F circuit FFI1 will be described. In the case where the input-stage F/F circuit FFI1 is designated by the external test control signal T-CTL and the test signal T-DI, the input-stage test circuit TSI-1 corresponding to the input-stage F/F circuit FFI1 supplies the internal test clock signal TSCLK as a sync clock signal of the input-stage F/F circuit FFI1. On the other hand, in the normal operation, the corresponding input-stage test circuit TSI-1 supplies the internal operation clock signal OCLK as a sync clock signal to the input-stage F/F circuit FFI1.

In other words, the input-stage test circuit can be regarded as a selection circuit of selecting which of the internal test clock signal TSCLK or the internal operation clock signal OCLK is used as the sync clock signal supplied to the corresponding input-stage F/F circuit.

An output of each of the input-stage F/F circuits FFI1 to FFIp is coupled to an input of the processor CPU. At the time of outputting a result of the operation timing test, the input-stage F/F circuits FFI1 to FFIp are controlled by corresponding input-stage test circuits so as to be coupled in series between the input terminal Pdi and the output terminal Pdo.

Specifically, at the time of outputting a result of an operation timing test, the input-stage test circuit couples an input of the corresponding input-stage F/F circuit to the input-stage F/F circuit corresponding to the front stage in the input-stage F/F circuits coupled in series. For example, the input-stage test circuit TSI-2 couples an input of the corresponding input-stage F/F circuit FFI2 to the output of the input-stage F/F circuit FFI1 in the front stage. At the time of outputting a result of the operation timing test by the corresponding input-stage test circuit TSI-1, the input of the input-stage F/F circuit FFI1 is coupled to the input terminal Pdi, and the output of the input-stage F/F circuit FFIp is coupled to the output terminal Pdo. When a result of the operation timing test is output, the input-stage F/F circuits are coupled in series and, therefore, can be regarded that they configure a shift register. In this case, a shifting operation is performed synchronously with the internal test clock signal TSCLK. In other words, the input-stage test circuit can be regarded as a selection circuit of selecting an input of a corresponding input-stage F/F circuit.

In FIG. 1, IRSL denotes an input path selecting circuit. Via the input path selecting circuit IRSL and the input-first-stage F/F circuit FFI, the input terminals Pi1 to Pin are coupled to the processor CPU. The input path selecting circuit IRSL selects a path coupling between the input terminals Pi1 to Pin to the input-first-stage F/F circuit FFI in accordance with an input path selection signal. That is, an input path instructed by the input path selection signal is formed between an input terminal and an input-stage F/F circuit. For example, by the input path selection signal, an input path is formed between the input terminal Pi1 and the input-stage F/F circuit FFI2. In such a manner, an arbitrary input terminal can be coupled to an arbitrary input-stage F/F circuit.

The input path selection signal is formed by an input path selection control circuit RSC-I and an input path test circuit TST-I.

When the semiconductor device CHP is operated normally, that is, when a predetermined process which is determined by the user is executed by the processor CPU as the process unit, the input path selection control circuit RSC-I generates an input path selection signal synchronously with the internal operation clock signal OCLK. When the semiconductor device CHP is operated normally, the input path selection control circuit RSC-I is set by the user so that an input signal in a desired input terminal in the input terminals Pi1 to Pin of the semiconductor device CHP is transmitted to a desired input of the processor CPU. That is, the input path control circuit RSC-I is configured by the user so that an input path selection signal by which an input signal at a desired input terminal is transmitted to a desired input of the processor in the normal operation is generated by the input path selection control circuit RSC-I. For example, in the normal operation, a program is generated by the user so that a desired input path is formed, and is stored in the memory EROM. In the normal operation, the program is executed by the processor CPU, the input path selection control circuit RSC-I is controlled by the processor CPU, and a desired input path is formed.

In contrast, the input path test circuit TST-I generates an input path selection signal synchronously with the internal test clock signal TSCLK in an operation timing test. In this case, the input path selection signal generated by the input path test circuit TST-I is determined by the external test control signal T-CTL which is supplied to the input terminal Pct. That is, by the value of the external test control signal T-CTL, the input path selection circuit IRSL forms a path between an input terminal and an input-stage F/F circuit.

An output of each of the input-stage F/F circuits FFI1 to FFIp is coupled to an input of the processor CPU. By making the semiconductor device CHP perform normal operation, an input signal supplied to an arbitrary input terminal can be transmitted to a desired input of the processor CPU by the input path selection signal. In an operation timing test, the input path selection signal according to the external test control signal T-CTL is generated, so that an input signal at a desired input terminal can be transmitted to an input of a desired input-stage F/F circuit.

The output final-stage F/F circuit FFO also has a plurality of output-stage F/F circuits FFO1 to FFOp and output-stage test circuits TSO-1 to TSO-p. Each of the output-stage F/F circuits FFO1 to FFOp may configured by a single output F/F circuit or by a plurality of output F/F circuits. The output-stage F/F circuits FFO1 to FFOp correspond to the output-stage test circuits TSO-1 to TSO-p on a one-to-one basis. Although not limited, in the first embodiment, the output F/F circuits configuring the output-stage F/F circuits FFO1 to FFOp have the same configuration, and the output-stage test circuits TSO-1 to TSO-p also have similar configurations.

Each of the output-stage test circuits TSO-1 to TSO-p is controlled by the test signal T-DI and the test control signal T-CTL in an operation timing test. Specifically, in an operation timing test, the output-stage test circuits TSO-1 to TSO-p select an output-stage F/F circuit designated by the external test control signal T-CTL and the test signal T-DI in the output-stage F/F circuits FFO1 to FFOp configuring the output-final-stage F/F circuit. To the selected output-stage F/F circuit, the test signal T-DI from the input terminal Pdi is supplied. To the selected output-stage F/F circuit, as a synch clock signal, the internal test clock signal TSCLK is supplied. In a normal operation, the output-stage test circuits TSO-1 to TSO-p transmit an output signal from the processor CPU to the input of the corresponding output-stage F/F circuit, and supply the internal operation clock signal OCLK as a sync clock signal.

The output-stage F/F circuit FFO1 will be described as an example. In the case where the output-stage F/F circuit FFO1 is designated by the external test control signal T-CTL and the test signal T-DI, in an operation timing test, the corresponding output-stage test circuit TSO-1 supplies the test signal T-DI via the input terminal Pdi to the input of the output-stage F/F circuit FFO1, and supplies the internal test clock signal TSCLK as a sync clock signal. In a normal operation, the output-stage test circuit TSO-1 transmits an output signal from the processor CPU to an input of the corresponding output-stage F/F circuit FFO1 and supplies the internal operation clock signal OCLK as a sync clock signal.

In the operation timing test, the output-stage F/F circuits FFO1 to FFOp are controlled so as to be coupled in series between the input terminal Pdi and the output terminal Pdo by the output-stage test circuits TSO-1 to TSO-p. That is, when coupled in the series, an input of each of the output-stage F/F circuits FFO2 to FFOp is coupled to the output of the output-stage F/F circuit corresponding to the front stage. The output-stage F/F circuit FFO2 will be described as an example. The input of the output-stage F/F circuit FFO2 is controlled by the corresponding output-stage test circuit TSO-2 so as to be coupled to the output of the output-stage F/F circuit FFO1 of the front stage. The output of the output-stage F/F circuit FFOp is coupled to the output terminal Pdo. Consequently, it can be regarded that, in the operation timing test, a shift register is configured by the output-stage F/F circuits FFO1 to FFOp. In this case, the shifting operation of the shift register is performed synchronously with the internal test clock signal TSCLK.

In other words, the output-stage test circuit can be regarded as a selection circuit of selecting which of an input signal supplied to the input of the corresponding output-stage F/F circuit or the sync clock signal of the corresponding output-stage F/F circuit.

The outputs of the output-stage F/F circuits FFO1 to FFOp are coupled to the output terminals Po1 to Pon via the output path selection circuit ORSL. In a manner similar to the input path selection circuit ISRL, the output path selection circuit ORSL selects paths coupling between the output terminals Po1 to Pon and the output-final-stage F/F circuit FFO in accordance with the output path selection signal. That is, the output path instructed by the output path selection signal is formed between the output terminal and the output-stage F/F circuit. For example, by the output path selection signal, an output path is formed between the output terminal Po1 and the output-stage F/F circuit FFI2. In such a manner, an arbitrary output terminal can be coupled to an arbitrary output-stage F/F circuit.

The output path selection signal is generated by the output path selection control circuit RSC-O and the output path test circuit TST-O.

When the semiconductor device CHP is normally operated, the output path selection control circuit RSC-O generates the output path selection signal synchronously with the internal operation clock signal OCLK. When the semiconductor device CHP is normally operated, the output path selection control circuit RSC-O is set by the user so that a desired output signal is transmitted from the processor CPU to a desired output terminal of the output terminals Po1 to Pon of the semiconductor device CHP. That is, the output path control circuit RSC-O is configured by the user so that an output path selection signal by which a desired output signal from the processor CPU is transmitted to a desired output terminal is generated by the output path selection control circuit RSC-O in the normal operation. For example, like the input path selection circuit, by executing a program of the user by the processor CPU, a desired output path is formed.

In contrast, the output path test circuit TST-O generates an output path selection signal synchronously with the internal test clock signal TSCLK in an operation timing test. In this case, the output path selection signal generated by the output path test circuit TST-O is determined by the external test control signal T-CTL which is supplied to the input terminal Pct. That is, by the value of the external test control signal T-CTL, the output path selection circuit ORSL forms paths between the output terminals Po1 to Pon and the output-stage F/F circuits FFO1 to FFOp.

In FIG. 1, to avoid complication of the diagram, each of the input terminals Pdi and Pct is illustrated as a single terminal. However, it is to be understood that a plurality of terminals exist. The input terminal Pck and the output terminal Pco are coupled by a signal line L2. The external test clock signal T-CLK supplied to the input terminal Pck propagates as the internal test clock signal TSCLK through the signal line L2 and is transmitted to the output terminal Pco. To the input terminal Pet, the external operation clock signal Ex-CLK is supplied. The external operation clock signal Ex-CLK is supplied to a clock generation circuit CLKG via the input terminal Pet. In the clock generation circuit CLKG, the internal operation clock signal OCLK synchronized with the external operation clock signal Ex-CLK is generated and supplied to the above-described circuit blocks via a signal line L1.

In the above-described circuit blocks, the clock generation circuit CLKG, the input path selection circuit IRSL, the input-stage F/F circuits FFI1 to FFIp, the input path selection control circuit RSC-I, the processor CPU, the output-stage F/F circuits FFO1 to FFOp, the signal line L1, the output path selection circuit ORSL, and the output path control circuit RSC-O can be regarded as user circuits provided for the semiconductor device CHP by the user to achieve desired functions by the semiconductor device CHP. Similarly, the output terminals Pi1 to Pin, Pet, and Po1 to Pon and the signal line L1 can be also regarded as a part of the user circuits. In contract, the output-stage test circuits TSO-1 to TSO-p (first selection circuits) , the output path test circuit TST-O (second selection circuit), the input-stage test circuits TSI-1 to TSI-p (third selection circuits or first selection circuits), and the input path test circuit TST-I (fourth selection circuit or second selection circuit) can be regarded as circuit blocks added for the operation timing test. The signal line L2 and the external terminals Pdi, Pct, Pck, Pco, and Pdo can be also regarded as elements added for the operation timing test.

### Outline of Operation

### Normal Operation

By the path selection signal generated by the input path selection control circuit RSC-I, the input path selection circuit IRSL forms input paths between the input terminal Pi1 to Pin and the input-stage F/F circuits FFI1 to FFIp. By the input paths, for example, each of the input terminals Pi1 to Pin is coupled to the input of an input-stage F/F circuit desired by the user. Similarly, by the path selection signal generated by the output path selection control circuit RSC-O, the output path selection circuit ORSL forms output paths between the output terminals Po1 to Pon and the output-stage F/F circuits FFO1 to FFOp. By the output paths, for example, output signals of the output-stage F/F circuits FFO1 to FFOn are transmitted to the output terminals Po1 to Pon desired by the user, respectively.

The input-stage F/F circuits FFI1 to FFIp fetch signals according to the input signals supplied to the input terminals Pi1 to Pin synchronously with the internal operation clock signal OCLK and output them. The output signals output from the input-stage F/F circuits FFI1 to FFIp are input to the processor CPU. The processor CPU executes a process on an output signal supplied from the input-stage F/F circuit in accordance with the program stored in the memory EROM. Since the F/F circuits FF synchronized with the internal operation clock signal OCLK are used in this process, the processor CPU executes the process synchronously with the internal operation clock signal OCLK.

By the process executed in the processor CPU, the processor CPU generates a plurality of output signals and outputs them. The output signals output from the processor CPU are transmitted to the output-stage F/F circuits FFO1 to FFOp, taken by the output-stage F/F circuits FFO1 to FFOp synchronously with the internal operation clock signal OCLK, and output. Output signals output from the output-stage F/F circuits FFO1 to FFOp are transmitted to the output terminals Po1 to Pon desired by the user via the output path selection circuit ORSL and output.

### Operation Timing Test

First, the operation timing test of the output system will be described. For example, by the external test control signal T-CTL and the test signal T-DI, the output-stage F/F circuits FFO1 to FFOp are selected. By the above, the output-stage test circuits TSO-1 to TSO-p select and supply the internal test clock signal TSCLK as a sync clock signal to the corresponding output-stage F/F circuits FFO1 to FFOp. The inputs of the output-stage F/F circuits are selected so as to couple the output-stage F/F circuits FFO1 to FFOp in series between the input terminal Pdi and the output terminal Pdo.

For example, series data of logic values “1” and “0” is set as a test pattern, and the test pattern is supplied as the test signal T-DI to the input terminal Pdi. Consequently, when the internal test clock signal TSCLK changes periodically, the test pattern is sequentially transferred in the output-stage F/F circuits FFO1 to FFOp coupled in series. That is, the test pattern sequentially shifts in the shift register synchronously with the internal test clock signal TSCLK.

On the basis of the external test control signal T-CTL, the output path test circuit TST-O generates a path selection signal, and the output of the output-stage F/F circuit is transmitted to the desired output terminal Po1 to Pon via the output path selection circuit.

At this time, to the output terminal Pco, the internal test clock signal TSCLK propagated through the signal line L2 is transmitted. Consequently, by obtaining the time difference between a signal change in the output terminal Pco and a signal change in the output terminals Po1 to Pon, delay time can be obtained. For example, in the case where impedance of lines (including leads) between the output-stage F/F circuits FFO1 to FFOp and the external terminals Po1 to Pon are undesirably high, delay time is long. Therefore, it can be detected by the operation timing test.

Next, the operation timing test of the input system will be described. For example, by the external test control signal T-CTL and the test signal T-DI, the input-stage F/F circuits FFI1 to FFIp are selected. By the operation, the input-stage test circuits TSI-1 to TSI-p select and supply the internal test clock signal TSCLK as a sync clock signal to the corresponding input-stage F/F circuits FFI1 to FFIp.

On the basis of the test control signal T-CTL, the input path test circuit TST-I generates a path selection signal, and the input signal in each of the input terminals Pi1 to Pin is transmitted to a desired input-stage F/F circuit via the input path selection circuit IRSL. Next, to the input terminals Pi1 to Pin, test patterns are supplied, for example, in parallel in time. The test patterns supplied to the input terminals Pi1 to Pin are transmitted to the inputs of the input-stage F/F circuits FFI1 to FFIp via the input path selection circuit IRSL. The test patterns transmitted to the inputs are fetched by the input-stage F/F circuits FFI1 to FFIp synchronously with the internal test clock signal TSCLK.

Subsequently, the input-stage F/F circuits FFI1 to FFIp are coupled in series between the input terminal Pdi and the output terminal Pdo. By changing the internal test clock signal TSCLK, the test pattern taken in the input-stage F/F circuits FFI1 to FFIp is sequentially transferred in the input-stage F/F circuits FFI1 to FFIp which are coupled in series, and is output from the output terminal Pdo.

By performing a determination of whether the logic value of the output signal output from the output terminal Pdo matches an expectation value for the test pattern or not, whether a signal according to the test pattern is fetched in the input-stage F/F circuits or not is determined. For example, in the case where impedance of lines (including leads) between the input-stage F/F circuits FFI1 to FFIp and the input terminals Pi1 to Pin is undesirably high, time required for the signal according to the test pattern to reach the input-stage F/F circuit is long. Therefore, a case occurs such that, when the internal test clock signal TSCLK changes, the signal according to the test pattern is not fetched by the input-stage F/F circuit, and the value output from the output terminal Pdo does not match the expectation value of the test pattern. In this case, the time difference between the timing of the external test clock signal T-CLK when the expectation value of the test pattern and an output from the output terminal Pdo match and the timing of supplying the test pattern to the input terminal corresponds to delay time of the input signal.

In FIG. 1, the flows of the test pattern in the output-system operation timing test are indicated by arrowed broken lines O1 to Op, and the flows of the test pattern in the input-system operation timing test are indicated by arrowed broken lines I1 to Ip. The main flow of the internal test clock signal TSCLK is indicated by an arrowed broken line TCK.

The output-system operation timing test and the input-system operation timing test may be executed at the same time or executed time-differentially.

In the first embodiment, the example of coupling the input-stage F/F circuits FFI1 to FFIp in series and taking a signal according to a test pattern fetched by an input-stage F/F circuit from the output terminal Pdo has been described. However, the present invention is not limited to the example. For example, values according to a test pattern fetched by the input-stage F/F circuits may be taken in parallel. Similarly, although it has been described that the output-stage F/F circuits FFO1 to FFOp are coupled in series, a test pattern may be set to each of the output-stage F/F circuits FFO1 to FFOp. However, by coupling the input-stage F/F circuits in series and also coupling the output-stage F/F circuits in series, increase in the number of external terminals can be suppressed.

The input-stage F/F circuits FFI1 to FFIp coupled in series function as an input-side shift register which operates synchronously with the internal test clock signal TSCLK, and the output-stage F/F circuits FFO1 to FFOp coupled in series function as an output-stage shift register which operates synchronously with the internal test clock signal TSCLK. The input-side shift register and the output-side shift register can be used as a shift register at the time of executing a scan path test to the processor CPU. Specifically, the test pattern of the scan path test is set in the input-side shift register sequentially from the input terminal Pdi. After that, an output from the processor CPU is fetched in the output-side shift register. By sequentially taking out the values fetched in the output-side shift register from the output terminal Pdo, the scan path test can be executed.

In FIG. 1, black triangles illustrated in the input-stage F/F circuit and the output-stage F/F circuit indicate clock input terminals of the F/F circuits, to which the sync clock signal is supplied.

### Configuration of Output System

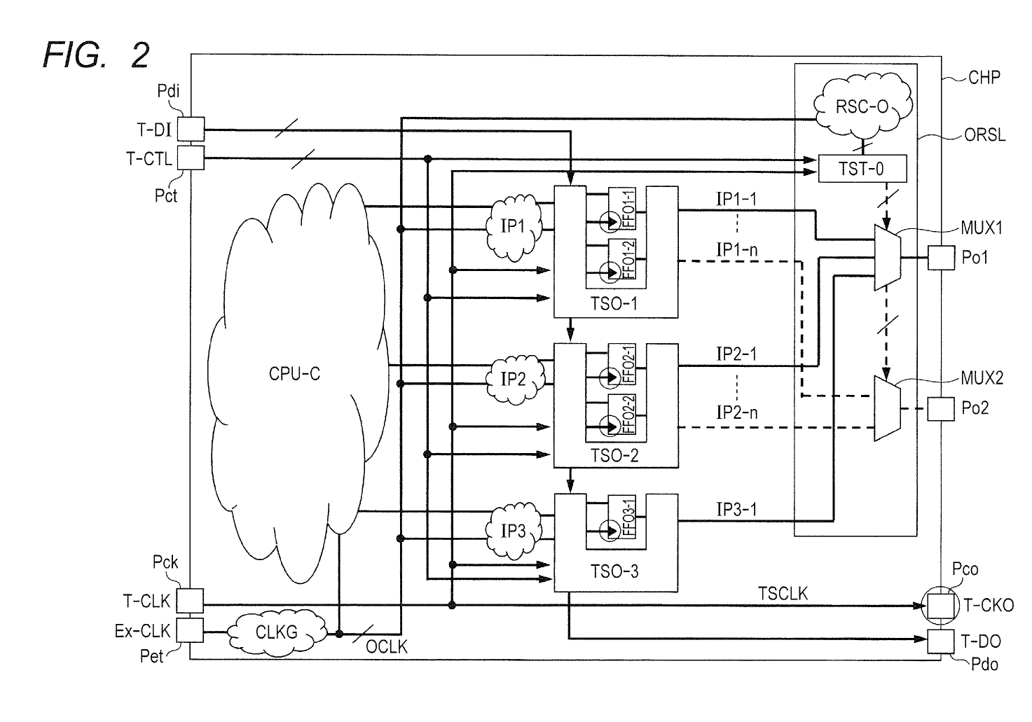

FIG. 2 is a block diagram more specifically illustrating the configuration of the output system in the semiconductor device CHP illustrated in FIG. 1. Although the processor CPU is illustrated in a single circuit block in FIG. 1, the processor CPU has a control unit performing a control on processes and a plurality of function units controlled by the control unit and having various functions. The function units include, for example, a function unit performing a serial communication, a function unit performing SPI (Serial Peripheral Interface), and a function unit performing CAN (Controller Area Network). In FIG. 2, the control unit is illustrated as CPU-C, and the function units are illustrated as IP1 to IP3.

To the control unit CPU-C and the function units IP1 to IP3, the internal operation clock signal OCLK generated by the clock generation circuit CLKG is supplied. In FIG. 1, the internal operation clock signal OCLK is illustrated as a single signal. However, there are a plurality of clock signals concretely. Specifically, clock signals of frequencies which are proper in the control unit CPU-C and the function units IP1 to IP3 are generated by the clock generation circuit CLKG. Obviously, the clock signals are synchronized with one another. Consequently, the clock signals generated by the clock generation circuit CLKG will be collectively described as the internal operation clock signal OCLK.

Each of the function units IP1 to 1P3 receives a control signal and data from the control unit CPU-C and generates an output signal according to its function. Obviously, the function units operate synchronously with the internal operation clock signal OCLK. In the first embodiment, an output signal of the function unit IP1 is supplied to the output-stage F/F circuit FFO1, an output signal of the function unit IP2 is supplied to the output-stage F/F circuit FFO2, and an output signal of the function unit IP3 is supplied to the output-stage F/F circuit FFO3. Although each of the output-stage F/F circuits FFO1 and FFO2 has a plurality of output F/F circuits in the first embodiment, in FIG. 2, two output F/F circuits FFO1-1 and FFO1-2 and two output F/F circuits FFO2-1 and FFO2-2 in the output F/F circuits are illustrated. An example that the output-stage F/F circuit FFO3 is configured by a single output F/F circuit FFO3-1 is illustrated. In FIG. 2, the black triangles in the output F/F circuits indicate clock input terminals of the F/F circuits.

In the normal operation, the output-stage test circuit TSO-1 selects the internal operation clock signal OCLK as a sync clock signal supplied to the clock input terminal (black triangle) of the corresponding output-stage F/F circuit FFO1 (the output F/F circuits FFO1-1 and FFO1-2) and supplies it. In the normal operation, the output-stage test circuit TSO-1 supplies an output signal from the function unit IP1 to the output-stage F/F circuit FFO1 (the output F/F circuits FFO1-1 and FFO1-2). When the internal operation clock signal OCLK changes, the output-stage F/F circuit FFO1 (the output F/F circuits FFO1-1 and FFO1-2) fetches the output signal from the function unit IP1 at that time, holds it, and outputs it. In FIG. 2, output signals output from the output-stage F/F circuit FFO1 (the output F/F circuits FFO1-1, FFO1-2, and so on) are indicated as IP1-1 to IP1-n.

On the other hand, in an operation timing test, the output-stage test circuit TSO-1 supplies the test signal T-DI to the corresponding output-stage F/F circuit FFO1 (the output F/F circuits FFO1-1 and FFO1-2), and supplies the internal test clock signal TSCLK as a sync clock signal supplied to the clock input terminal (black triangle). Consequently, when the internal test clock signal TSCLK changes, the output-stage F/F circuit FFO1 (the output F/F circuits FFO1-1 and FFO1-2) fetches the test signal T-DI, holds it, and outputs it as the output signals IP1-1 to IP1-n.

The output-stage test circuit TSO-2 is similar to the output-stage test circuit TSO-1. That is, in the normal operation, the output-stage test circuit TSO-2 supplies an output signal from the corresponding function unit IP2 and the internal operation clock signal OCLK to the corresponding output-stage F/F circuit FFO2. The output-stage F/F circuit FFO2 fetches an output signal from the function unit IP2 synchronously with the internal operation clock signal OCLK and outputs it as output signals IP2-1 to IP2-n. In the operation timing test, an output signal from the corresponding function unit IP2 and the internal test clock signal TSCLK are supplied to the corresponding output-stage F/F circuit FFO2. The output-stage F/F circuit FFO2 fetches an output signal from the function unit IP2 synchronously with the internal test clock signal TSCLK and outputs it as the output signals IP2-1 to IP2-n.

In the normal operation, like the output-stage test circuit TSO-2, the output-stage test circuit TSO-3 supplies an output signal from the corresponding function unit IP3 and the internal operation clock signal OCLK to the corresponding output-stage F/F circuit FFO3. The output-stage F/F circuit FFO3 fetches an output signal from the function unit IP3 synchronously with the internal operation clock signal OCLK and outputs it as an output signal IP3-1. In the operation timing test, an output signal from the corresponding function unit IP3 and the internal test clock signal TSCLK are supplied to the corresponding output-stage F/F circuit FFO3. The output-stage F/F circuit FFO3 fetches an output signal from the function unit IP3 synchronously with the internal test clock signal TSCLK and outputs it as the output signal IP3-1.

Although the output signals output from the output-stage test circuits TSO-1 to TSO-3 have been described as IP1-1 to IP1-n, IP2-1 to IP2-n, and IP3-1, it is to be noted that the output signals in the normal operation and those in the operation timing test are different. Specifically, the output signals IP1-1 to IP1-n, IP2-1 to IP2-n, and IP3-1 in the normal operation are values according to the output signals of the corresponding function unit. In contrast, the output signals in the operation timing test are values according to the test pattern.

The output signals IP1-1 to IP1-n, IP2-1 to IP2-n, and IP3-1 are supplied to the output path selection circuit ORSL. In FIG. 1, the output path selection circuit ORSL, the output path test circuit TST-O, and the output path selection control circuit RSC-O are separately illustrated. For convenience of explanation, in FIG. 2, it is illustrated that the output path selection circuit ORSL includes the output path test circuit TST-O and the output path selection control circuit RSC-O. Obviously, the output path test circuit TST-0 and the output path selection control circuit RSC-O may be provided separately from the output path selection circuit ORSL like in FIG. 1.

In the first embodiment, the output path selection circuit ORSL also has a plurality of selectors. The selectors transmit output signals from an output-stage test circuit designated by an output path selection signal from the output path test circuit TST-O or the output path selection control circuit RSC-O to the output terminals Po1 to Pon. In FIG. 2, the selectors corresponding to the output-stage test circuits TSO-1 to TSO-3 in those selectors are illustrated as selectors MUX1 and MUX2. Although not limited, the output signals IP1-1, IP2-1, and IP3-1 are supplied to the selector MUX1, and the output signals IP1-n and IP2-n are supplied to the selector MUX2. An output of the selector MUX1 is coupled to the output terminal Po1, and an output of the selector MUX2 is coupled to the output terminal Po2.

To the selectors MUX1 and MUX2, as selection signals for selecting an input, the output path selection signals from the output path test circuit TST-O and the output path selection control circuit RSC-O are supplied. In the normal operation, according to the output path selection signal from the output path selection control circuit RSC-O, the selector MUX1 selects any of the output signals IP1-1, IP2-1, and IP3-1 and transmits the selected output signal to the output terminal Po1. Similarly, the selector MUX2 selects any of the output signals IP1-n and IP2-n in accordance with the output path selection signal from the output path selection control circuit RSC-O and transmits the selected output signal to the output terminal Po2. In the normal operation, selection of an output signal is determined by the user. For example, selection of an output signal is determined by a program stored in the memory EROM.

On the other hand, in the operation timing test, the output path test circuit TST-O generates an output path selection signal in accordance with the external test control signal T-CTL. That is, according to the external test control signal T-CTL, each of the selectors MUX1 and MUX2 can determine an output signal to be selected. The output signal selected by the external test control signal T-CTL is transmitted to the output terminals Po1 and Pot via the selectors MUX1 and MUX2. In the embodiment, the output path test circuit TST-O operates synchronously with the internal test clock signal TSCLK. That is, in the operation timing test, the output path selection signal is generated synchronously with the internal test clock signal TSCLK. In such a manner, in the operation timing test, the output path selection signal can be generated without fail.

In the first embodiment, disposition of signal lines (for example, L2 in FIG. 1) and the like is adjusted so that the timing of the internal test clock signal TSCLK reaching the clock input terminal (black triangle) of each of the output F/F circuits FFO1-1, FFO1-2, FFO2-1, FFO2-2, and FFO3-1 and the timing of the test clock signal reaching the output terminal Pco match. In FIG. 2, parts in which the timings are matched are surrounded by circles.

### Configuration of Output-Stage Test Circuit and Output-Stage F/F Circuit

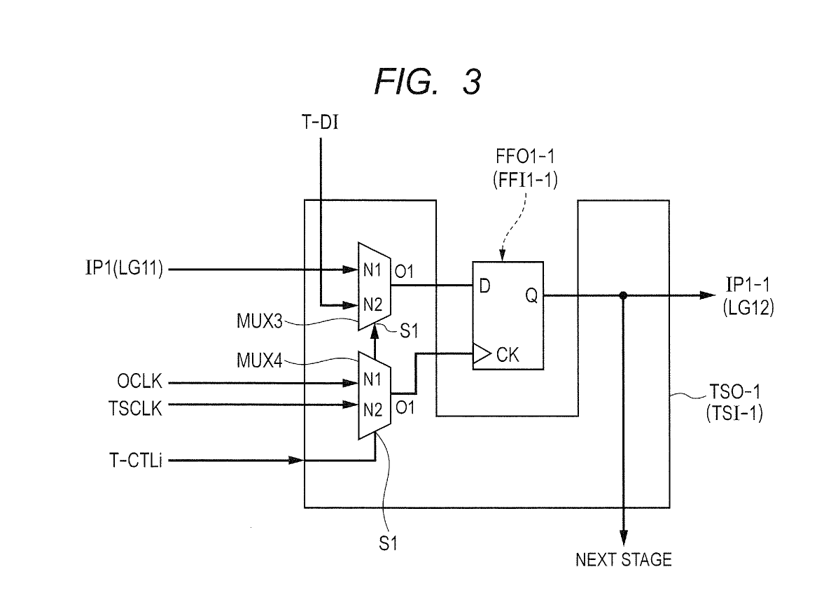

FIG. 3 is a block diagram illustrating the configuration of the output-stage test circuit and the output-stage F/F circuit. In FIG. 3, the configuration of the output F/F circuit FFO1-1 in the output-stage test circuit TSO-1 and the output-stage F/F circuit FFO1 illustrated in FIG. 2 is illustrated. The output-stage test circuits TSO-1 to TSO-p have similar configurations, and the output-stage F/F circuits FFO1 to FFOp also have similar configurations. Consequently, the configurations of the output-stage test circuit and the output-stage F/F circuit will be described using the output F/F circuit FFO1-1 in the output-stage test circuit TSO-1 and the output-stage F/F circuit FFO1 as an example.

The output F/F circuit FFO1-1 as a component of the output-stage F/F circuit FFO1 is comprised of a flip flop circuit having a clock input terminal CK, a data input terminal D, and a data output terminal Q. When the clock signal supplied to the clock input terminal CK changes, the output F/F circuit FFO1-1 fetches an input signal supplied to the data input terminal D at that time and holds it. The output F/F circuit FFO1-1 outputs an output signal (logic value) corresponding to the held value from the data output terminal Q. For example, when the clock signal supplied to the clock input terminal CK changes from the low level to the high level, the output F/F circuit FFO1-1 fetches the logic value of the input signal supplied to the data input terminal D at that time and holds the fetched logic value. The output F/F circuit FFO1-1 outputs the output signal having a voltage according to the held logic value from the data output terminal Q.

In the first embodiment, a clock signal supplied to the clock input terminal CK is a sync clock signal. Consequently, synchronously with a change in the sync clock signal supplied to the clock input terminal CK, the output F/F circuit FFO1-1 fetches the input signal and outputs it.

The output-stage test circuit TSO-1 has selectors MUX3 and MUX4. In the embodiment, each of the selectors MUX3 and MUX4 has two input terminals N1 and N2, a selection terminal S1, and an output terminal O1. Each of the selectors MUX3 and MUX4 selects any one of signals supplied to the input terminals N1 and N2 in accordance with a control signal supplied to the selection terminal S1 and transmits it to the output terminal O1.

In the output-stage test circuit TSO-1, to the selection terminal S1 of each of the selectors MUX3 and MUX4, the test selection control signal T-CTLi (i=1 to p) is supplied. To the input terminal N1 of the selector MUX3, an output signal from the function unit IP1 is supplied. To the input terminal N2, the test signal T-DI is supplied from the input terminal Pdi. To the input terminal N1 of the selector MUX4, the internal operation clock signal OCLK is supplied. To the input terminal N2, the internal test clock signal TSCLK is supplied. The output terminal O1 of the selector MUX3 is coupled to the data input terminal D of the output F/F circuit FFO1-1, and the output terminal O1 of the selector MUX4 is coupled to the clock input terminal CK of the output F/F circuit FFO1-1.

The data output terminal Q of the output F/F circuit FFO1-1 is coupled to the input of the selector MUX1 in the output path selection circuit ORSL as the output signal IP1-1 via a not-illustrated signal line. When the output F/F circuits are coupled in series, the data output terminal Q of the output F/F circuit FFO1-1 is coupled to the input terminal N2 of the selector MUX3 corresponding to the output F/F circuit at the next stage. Referring to FIG. 2, when a test pattern is set in the output F/F circuits FFO1-1, FFO1-2, FFO2-1, FFO2-2, and FFO3-1 by the test signal T-DI, the output F/F circuits are coupled in series between the input terminal Pdi and the output terminal Pdo. That is, the output F/F circuits FFO1-1, FFO1-2, FFO2-1, FFO2-2, and FFO3-1 are coupled in order between the input terminal Pdi and the output terminal Pdo. Consequently, the output F/F circuit at the next stage of the output F/F circuit FFO1-1 is the output F/F circuit FFO1-2. Therefore, the data output terminal Q of the output F/F circuit FFO1-1 illustrated in FIG. 3 is coupled to the input terminal N2 of the selector MUX3 corresponding to the output F/F circuit FFO1-2.

In the output-stage test circuit TSO-1, the selectors MUX3 and MUX4 select signals supplied to the input terminal N1 or N2 synchronously, and transmit the selected signals to the output terminal O1. When the selector MUX3 selects an output signal from the function unit IP1 supplied to the input terminal N1 by the test selection control signal T-CTLi and outputs it from the output terminal O1, the selector MUX4 selects the internal operation clock signal OCLK supplied to the input terminal N1 by the test selection control signal T-CTLi and outputs it from the output terminal O1. When the selector MUX3 selects the test signal T-DI supplied to the input terminal N2 by the test selection control signal T-CTLi and outputs it from the output terminal O1, the selector MUX4 selects the internal test clock signal TSCLK supplied to the input terminal N2 by the test selection control signal T-CTLi and outputs it from the output terminal O1.

Although not limited, the test selection control signals T-CTLi (i=1 to p) correspond to the output-stage test circuits TSO-1 to TSO-p on a one-to-one basis. Specifically, referring to FIG. 2 as an example, the test selection control signal T-CTLi (i=1) is supplied to the output-stage test circuit TSO-1, the test selection control signal T-CTLi (i=2) is supplied to the output-stage test circuit TSO-2, and the test selection control signal T-CTLi (i=3) is supplied to the output-stage test circuit TSO-3. The test selection control signal T-CTLi (i=1 to p) is generated on the basis of the external test control signal T-CTL and the test signal T-DI by a not-illustrated test control circuit. Although not limited, the test control circuit operates synchronously with the internal test clock signal TSCLK in the operation timing test and operates synchronously with the internal operation clock signal OCLK in the normal operation.

An example will be described later. In the operation timing test, a designation signal designating an output-stage F/F circuit to be tested is supplied as the test signal T-DI to the input terminal Pdi. On the basis of the designation signal, the test control circuit supplies the external test control signal T-CTL as the test selection control signal T-CTLi (i=1 to p) to the output-stage F/F circuit designated as a test target.

Each of the selectors MUX3 and MUX4 selects the signal supplied to the input terminal N1 when the test selection control signal T-CTLi does not designate the operation timing test (for example, in the normal operation) or does not designate the output F/F circuit FFO1 (output F/F circuit FFO1-1) in the operation timing test. On the other hand, when the test selection control signal T-CTLi instructs the output F/F circuit FFO1-1 in the operation timing test, the selectors MUX3 and MUX4 select the signal supplied to the input terminal N2.

In the normal operation or in the operation timing test, when the output F/F circuit FFO1-1 is not designated, the output-stage test circuit TSO-1 supplies, as a sync clock signal, the internal operation clock signal OCLK to the clock input terminal CK of the corresponding output F/F circuit FFO1-1. At this time, the output signal from the function unit IP1 is supplied to the data input terminal D of the output F/F circuit FFO1-1.

As a result, in the normal operation or in the operation timing test, when the output F/F circuit FFO1-1 is not designated, the output F/F circuit FFO1-1 fetches the output signal from the function unit IP1 synchronously with the internal operation clock signal OCLK, holds it, and outputs a signal corresponding to the held value as the output signal IP1-1. The output signal IP1-1 is also supplied to the input terminal N2 of the selector MUX3 corresponding to the output F/F circuit FFO1-2 of the next stage. However, in the normal operation, the selectors MUX3 and MUX4 corresponding to the output F/F circuit FFO1-2 of the next stage select the signal supplied to the input terminal N1. Consequently, to the data input terminal D of the output F/F circuit FFO1-2 of the next stage, the output signal from the output F/F circuit FFO1-1 of the front stage is not transmitted.

In the operation timing test, when the output F/F circuit FFO1-1 is designated, from the output-stage test circuit TSO-1 to the output F/F circuit FFO1-1, the internal test clock signal TSCLK is supplied as a sync clock signal to the clock input terminal CK, and the test signal T-DI is supplied to the data input terminal D. In the operation timing test, by changing the internal test clock signal TSCLK, the output F/F circuit FFO1-1 fetches the test signal T-DI, holds it, and outputs it. An output from the output F/F circuit FFO1-1 propagates through a signal line (not illustrated) and is further transmitted to the output terminals Po1 and Po2 via the output path selection circuit ORSL. Since the internal test clock signal TSCLK is transmitted also to the output terminal Pco, by obtaining the time difference between the change in the test clock signal T-CKO in the output terminal Pco and the change in the signal in the external terminals Po1 and Po2 which is the output signal transmitted from the output F/F circuit FFO1-1, the result of the operation timing test between the output F/F circuit FFO1-1 (output-stage F/F circuit FFO1) and the output terminal can be obtained.

For example, in the case of designating the output F/F circuits FFO1-1, FFO1-2, FFO2-1, FFO2-2, and FFO3-1 illustrated in FIG. 2 in the operation timing test, the output F/F circuits are coupled in series to form a shift register (register chain) by the output-stage test circuit. In this case, the test signal T-DI supplied to the input terminal Pdi is transferred sequentially in the shift register synchronously with the change in the internal test clock signal TSCLK. After that, by obtaining the time difference between the change in the test clock signal T-CKO in the output terminal Pco and the change in the signal in the output terminals Po1 and Po2, the result of the operation timing test between the output F/F circuit, in other words, the output-stage F/F circuit and the output terminals Po1 and Po2 can be obtained.

Designation of an output F/F circuit (or an output-stage F/F circuit) by the test selection control signal T-CTLi means execution of a test of an operation timing on an output path between the output F/F circuit (output-stage F/F circuit) and an output terminal. On the other hand, when an output F/F circuit (output-stage F/F circuit) is not designated, it means that a test of an operation timing is not executed on an output path between the output F/F circuit (output-stage F/F circuit) and an output terminal.

The clock input terminal CK of the F/F circuit is indicated by the black triangle in the diagrams other than FIG. 3.

### Configuration of Input System

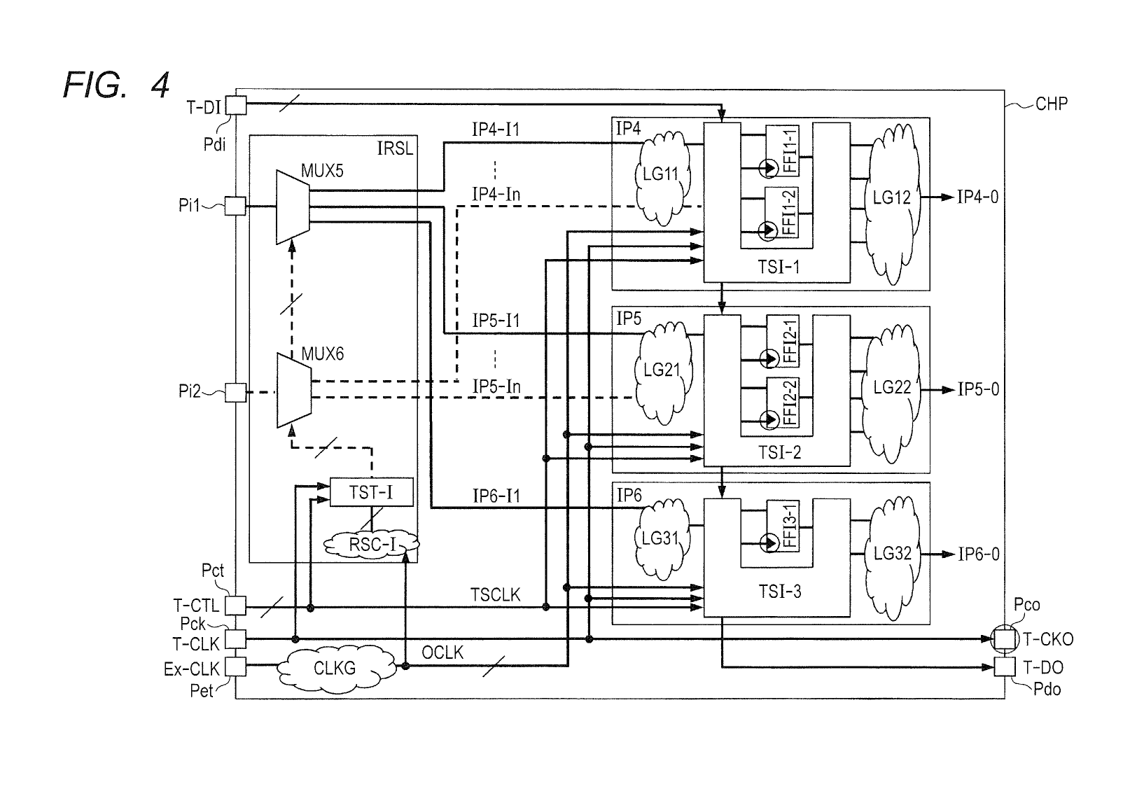

FIG. 4 is a block diagram more specifically illustrating the configuration of the input system in the semiconductor device CHP depicted in FIG. 1. As described with reference to FIG. 2, the processor CPU has the control unit CPU-C performing a control on processes and the function units having various functions. In FIG. 4, the function units are illustrated as IP4 to IP6. Although the control unit CPU-C is not illustrated in the diagram to avoid the diagram from becoming complicated, outputs of the function units IP4 to IP6 are supplied to the control unit CPU-C.

To the function units IP4 to IP6, the internal test clock signal TSCLK and the internal operation clock signal OCLK generated by the clock generation circuit CLKG are supplied. The clock generation circuit CLKG generates clock signals of proper frequencies in the function units IP4 to IP6, and the clock signals are synchronized with one another. Consequently, also in FIG. 4, the clock signals generated by the clock generation circuit CLKG will be collectively described as the internal operation clock signal OCLK.

Each of the function units IP4 to IP6 is controlled by a control signal (not illustrated) from the not-illustrated control unit CPU-C, receives input data from the input terminals Pi1 and Pi2, and generates an output signal according to its function. Although an example that each of the function units is provided with an input-stage F/F circuit and an input-stage test circuit will be described, the invention is not limited to the example.

The function unit IP4 has logic circuits LG11 and LG12, and an output of the logic circuit LG11 is supplied to the logic circuit LG12 via the input-stage test circuit TSI-1 and the input-stage F/F circuit FFI1. The input-stage F/F circuit FFI1 is comprised of a plurality of input F/F circuits. In FIG. 4, the input F/F circuit FFI1-1 and FFI1-2 in the input F/F circuits are illustrated as an example. The logic circuit LG11 receives a signal from the input path selection circuit IRSL as an input signal, generates an output signal, and supplies the output signal to the logic circuit LG12 via the input-stage test circuit TSI-1 and the input-stage F/F circuit FFI1. From the logic circuit LG12, an output signal IP4-O of the function unit IP4 is supplied to, for example, the control unit CPU-C. In FIG. 4, out of signals from the input path selection circuit IRSL supplied to the logic circuit LG11, input signals IP4-I1 to IP4-In are illustrated as an example.

The function unit IP5 also has, like the function unit IP4, logic circuits LG21 and LG22, and an output of the logic circuit LG21 is supplied to the logic circuit LG22 via the input-stage test circuit TSI-2 and the input-stage F/F circuit FFI2. The input-stage F/F circuit FFI2 is also comprised of a plurality of input F/F circuits. In FIG. 4, the input F/F circuit FFI2-1 and FFI2-2 in the input F/F circuits are illustrated as an example. The logic circuit LG21 receives a signal from the input path selection circuit IRSL as an input signal, generates an output signal, and supplies the output signal to the logic circuit LG22 via the input-stage test circuit TSI-2 and the input-stage F/F circuit FFI2. From the logic circuit LG22, an output signal IP5-O of the function unit IP5 is supplied to, for example, the control unit CPU-C. In FIG. 4, out of signals from the input path selection circuit IRSL supplied to the logic circuit LG21, input signals IP5-I1 to IP5-In are illustrated as an example.

The function unit IP6 also has logic circuits LG31 and LG32 for achieving the function, and an output of the logic circuit LG31 is supplied to the logic circuit LG32 via the input-stage test circuit TSI-3 and the input-stage F/F circuit FFI3. The input-stage F/F circuit FFI3 is comprised of an input F/F circuit FFI3-1. The logic circuit LG31 receives a signal from the input path selection circuit IRSL as an input signal IP6-I1, generates an output signal, and supplies the output signal to the logic circuit LG32 via the input-stage test circuit TSI-3 and the input-stage F/F circuit FFI3-1. From the logic circuit LG32, an output signal IP6-O of the function unit IP6 is supplied to, for example, the control unit CPU-C.

In the normal operation, the input-stage test circuit TSI-1 selects the internal operation clock signal OCLK as a sync clock signal supplied to the clock input terminal (black triangle) of the corresponding output-stage F/F circuit FFI1 (input F/F circuits FFI1-1 and FFI1-2) and supplies it. In the normal operation, the input-stage test circuit TSI-1 supplies an output signal from the logic circuit LG11 to the input F/F circuits FFI1-1 and FFI1-2. When the internal operation clock signal OCLK changes, the input F/F circuits FFI-1 and FFI-2 fetch the output signal from the logic circuit LG11 at that time, holds it, and supplies it to the logic circuit LG12.

In contrast, in an operation timing test, the input-stage test circuit TSI-1 supplies the internal test clock signal TSCLK to the clock input terminals (black triangles) of the corresponding input F/F circuits FFI1-1 and FFI1-2). Consequently, when the internal test clock signal TSCLK changes, the input F/F circuits FFI1-1 and FFI1-2 fetch the output signal from the logic circuit LG11 and hold it. That is, the output signals of the logic circuit LG11 generated by the logic circuit LG11 on the basis of the input signals IP4-I1 to IP4-In are fetched by the input F/F circuits FFI1-1 and FFI1-2 and held.

The input-stage test circuit TSI-2 is similar to the input-stage test circuit TSI-1. That is, in the normal operation, the input-stage test circuit TSI-2 selects a sync clock signal of the input-stage F/F circuit FFI2 so that the input-stage F/F circuit FFI2 (input F/F circuits FFI2-1 and FFI2-2) fetches an output signal from the corresponding logic circuit LG21 synchronously with the internal operation clock signal OCLK. The output signal fetched in the input-stage F/F circuit FFI2 and from the logic circuit LG21 held is supplied to the logic circuit LG22. On the other hand, at the time of the operation timing test, the input-stage test circuit TSI-2 selects a sync clock signal of the input-stage F/F circuit FFI2 so that the input-stage F/F circuit FFI2 fetches an output signal of a corresponding logic circuit LG21 synchronously with the internal test clock signal TSCLK.

Like the input test circuits TSI-1 and TSI-2, in the normal operation, the input test circuit TSI-3 selects the sync clock signal of the input-stage F/F circuit FFI3 so that the input-stage F/F circuit FFI3 (input F/F circuit FFI3-1) fetches an output signal from the logic circuit LG31 synchronously with the internal operation clock signal OCLK. The output signal from the logic circuit LG31, which is fetched and held in the input-stage F/F circuit FFI3, is supplied to the logic circuit LG32. On the other hand, at the time of the operation timing test, the input-stage test circuit TSI-3 selects a sync clock signal of the input-stage F/F circuit FFI3 so that the input-stage F/F circuit FFI3 fetches an output signal of a corresponding logic circuit synchronously with the test clock signal TSCLK.

In the operation timing test, a test pattern is supplied to the input terminals Pi1 and Pi2. Consequently, at the time of the operation timing test, the logic circuits LG11, LG21, and LG31 generate an output signal according to the test pattern and output it. At the time of the operation timing test, output signals of the logic circuits LG11, LG21, and LG31 held in the input-stage F/F circuits FFI1 (FFI1-1, FFI1-2), FFI2 (FFI2-1, FFI2-2), and FFI3 (FFI3-1) are output from the output terminal Pdo by coupling those input-stage F/F circuits in series.

That is, in the period of the operation timing test, the input-stage F/F circuits FFI1 (FFI1-1, FFI1-2), FFI2 (FFI2-1, FFI2-2), and FFI3 (FFI3-1) are coupled in series between the input terminal Pdi and the output terminal Pdo. In such a manner, a shift register (register chain) is configured by those input-stage F/F circuits. When the shift register is configured, the internal test clock signal TSCLK is used as a shift clock signal. Consequently, by changing the internal test clock signal TSCLK, the output signals held in the input-stage F/F circuits are sequentially output from the output terminal Pdo.

The input signals IP4-I1 to IP4-In, IP5-I1 to IP5-In, and IP6-I1 supplied to the logic circuits LG11, LG21, and LG31 are supplied from the input path selection circuit IRSL. In FIG. 1, the input path selection circuit IRSL, the input path test circuit TST-I, and the input path selection control circuit RSC-I are separately illustrated. For convenience of explanation, in FIG. 4, it is illustrated that the input path selection circuit IRSL includes the input path test circuit TST-I and the input path selection control circuit RSC-I. Obviously, the input path test circuit TST-I and the input path selection control circuit RSC-I may be provided separately from the input path selection circuit IRSL like in FIG. 1.

In the first embodiment, the input path selection circuit IRSL also has a plurality of selectors. The selectors transmit input signals from an input terminal, which are designated by the input path selection signal from the input path test circuit TST-I or the input path selection control circuit RSC-I to the logic circuit. In FIG. 4, the selectors corresponding to the input-stage test circuits TSI-1 to TSI-3 in those selectors are illustrated as selectors MUX5 and MUX6. Although not limited, a signal from the input terminal Pi1 is supplied to the selector MUX5, and signals are supplied as input signals IP4-I1, IP5-I1, or IP6-I1 to the logic circuits LG11, LG21, and LG31 via signal lines. A signal from the input terminal Pi2 is supplied to the selector MUX6, and is supplied as an input signal IP4-In or IP5-In to the logic circuits LG11 and LG21 via the signal lines.

To the selectors MUX5 and MUX6, as selection signals for selecting an output, the input path selection signals from the input path test circuit TST-I and the input path selection control circuit RSC-I are supplied.

In the normal operation, according to the input path selection signal from the input path selection control circuit RSC-I, the selector MUX5 transmits a signal supplied to the input terminal Pi1 as an input signal IP4-I1, IP5-I1, or IP6-I1 to the logic circuits LG11, LG21, and LG31. Similarly, according to the input path selection signal from the input path selection control circuit RSC-I, the selector MUX6 supplies the signal supplied to the input terminal Pi2 as the input signal IP4-In or IP5-In to the logic circuits LG11 and LG21. In the normal operation, selection of signals supplied to the input terminals Pi1 and Pi2 as an input signal is determined by the user . For example, selection of an input signal is determined by a program stored in the memory EROM. In this case, the input path selection control circuit RSC-I operates synchronously with the internal operation clock signal OCLK.

On the other hand, at the time of the operation timing test, the input path test circuit TST-I generates an input path selection signal in accordance with the external test control signal T-CTL. That is, according to the external test control signal T-CTL, each of the selectors MUX5 and MUX6 can determine an input signal to be selected. The input signal designated by the external test control signal T-CTL is transmitted to the logic circuits LG11, LG21, and LG31 via the selectors MUX5 and MUX6. In the embodiment, the input path test circuit TST-I operates synchronously with the internal test clock signal TSCLK. That is, at the time of the operation timing test, the input path selection signal is generated synchronously with the internal test clock signal TSCLK. In such a manner, at the time of the operation timing test, the input path selection signal can be generated without fail.

Also in FIG. 4, disposition of signal lines (for example, L2 in FIG. 1) and the like is adjusted so that the timing of the internal test clock signal TSCLK reaching the clock input terminal (black triangle) of each of the input F/F circuits FFI1-1, FFI1-2, FFI2-1, FFI2-2, and FFI3-1 and the timing of the test clock signal reaching the output terminal Pco match. Also in FIG. 4, parts in which the timings are matched are surrounded by circles.

### Configuration of Input-Stage Test Circuit and Input-Stage F/F Circuit

The configuration of the input-stage test circuits TSI-1 to TSI-3 and the input-stage F/F circuits FFI1-1 to FFI3 is similar to that of the output-stage test circuits TSO-1 to TSO-3 and the output-stage F/F circuits FFO1 to FFO3. Consequently, referring to FIG. 3, the configuration of the input-stage test circuit and the input-stage F/F circuit will be described mainly by parts different from the output-stage test circuit and the output-stage F/F circuit. The input-stage test circuits are similar to one another, and the input-stage F/F circuits are also similar to one another. The input-stage test circuit TSI-1 and the input-stage F/F circuit FFI1 (input F/F circuit FFI-1) will be described as an example. In FIG. 3, regarding parts of different reference numerals between the input-stage test circuit and the output-stage test circuit, reference numerals of the input-stage test circuit are written in parentheses. Similarly, regarding parts of different reference numerals between the input-stage F/F circuit (input F/F circuit) and the output-stage F/F circuit (output F/F circuit), reference numerals of the input-stage F/F circuit (input F/F circuit) are written in parentheses. Parts without parentheses after reference numerals are common to the input-stage test circuit and the output-stage test circuit, and are common to the input-stage F/F circuit and the output-stage F/F circuit.

The input-stage F/F circuit FFI1 has a plurality of input F/F circuits like the output-stage F/F circuit FFO1. However, in FIG. 3, only one input F/F circuit FFI1-1 is illustrated. The configuration of the input F/F circuit FFI1-1 is similar to that of the output F/F circuit FFO1-1. Specifically, the input F/F circuit FFI1-1 has the clock input terminal CK, the data input terminal D, and the data output terminal Q. When the clock signal supplied to the clock input terminal CK changes, an input signal supplied to the data input terminal D is fetched and held, and an output signal corresponding to the held signal is output from the data output terminal Q.

Like the output-stage test circuit TSO-1, the input-stage test circuit TSI-1 has the selectors MUX3 and MUX4. In the input-stage test circuit TSI-1, to the input terminal N1 of the selector MUX3, in place of the output signal from the function unit IP1, an output signal from the logic circuit LG11 is supplied. To the input terminal N2, the test signal T-DI is supplied. To the input terminals N1 and N2 of the selector MUX4, like the selector MUX4 of the output-stage test circuit TSO-1, the internal operation clock signal OCLK and the internal test clock signal TSCLK are supplied. Like the output terminals O1 of the selectors MUX3 and MUX4 of the output-stage test circuit TSO-1, the output terminal O1 of each of the selectors MUX3 and MUX4 of the input-stage test circuit TSI-1 is coupled to the data input terminal D and the clock input terminal CK of the input F/F circuit FFI1-1.

To the selection terminal S1 of each of the selectors MUX3 and MUX4 in the input-stage test circuit TSI-1, like the selection terminal S1 of each of the selectors MUX3 and MUX4 in the output-stage test circuit TSO-1, the test selection control signal T-CTLi (i=1 to p) generated by the test control circuit (not illustrated) is supplied. However, in the embodiment, the state of the selectors MUX3 and MUX4 designated by the test selection control signal T-CTLi is different from that in the input-stage test circuit TSI-1 and the output-stage test circuit TSO-1. That is, in the input-stage test circuit TSI-1, in the normal operation, like in the output-stage test circuit TSO-1, the selector MUX3 selects an output signal from the logic circuit LG11 which is supplied to the input terminal N1, and transmits it to the data input terminal D of the input F/F circuit FFI1-1. The selector MUX4 selects the internal operation clock signal OCLK supplied to the input terminal N1 and transmits it to the clock input terminal CK of the input F/F circuit FFI1-1.

On the other hand, in the case where the input F/F circuit FFI1-1 is designated in the operation timing test, according to the test selection control signal T-CTLi, the selector MUX3 selects the input terminal N1 and the selector MUX4 selects the input terminal N2. Specifically, the selector MUX3 selects an output signal from the logic circuit LG11 and transmits it to the data input terminal D. The selector MUX4 selects the internal test clock signal TSCLK and transmits it to the clock input terminal CK.

Consequently, in the normal operation, an output signal from the logic circuit LG11 is fetched in the input F/F circuit FFI1-1 synchronously with the internal operation clock signal OCLK and is supplied to the logic circuit LG12 from the data output terminal Q of the input F/F circuit FFI1-1. As a result, the process of the function unit IP4 is performed on the input signals supplied to the input terminals Pi1 and Pi2 illustrated in FIG. 4, and the output signal IP4-O of the function unit IP4 is supplied to the control unit CPU-C. That is, the process of the function unit IP4 is performed and its result is provided to the control unit CPU-C.

On the other hand, in the operation timing test, when the input F/F circuit FFI1-1 is designated, that is, when an operation timing test for the signal lines provided between the input terminals Pi1 and Pi2 and the input F/F circuit FFI1-1 and the logic circuit is instructed, the following is performed. The input-stage test circuit TSI-1 selects the internal test clock signal TSCLK as the sync clock signal of the input F/F circuit FFI1-1 and supplies it to the clock input terminal CK. At this time, the input-stage test circuit TSI-1 selects an output signal from the logic circuit LG11 and supplies it to the data input terminal D.

Consequently, the input F/F circuit FFI-1 fetches the output signal from the logic circuit LG11 synchronously with the internal test clock signal TSCLK and holds it. Consequently, in the operation timing test, by supplying the test pattern to the input terminals Pi1 and Pi2, an output signal from the logic circuit LG11 according to the test pattern is fetched in the input F/F circuit FFI1-1 at a change timing of the internal test clock signal TSCLK and held. According to whether, for example, a signal delay exceeding a predetermined delay occurs or not in the signal lines provided between the input terminals Pi1 and Pi2 and the input F/F circuit FFI1-1, and the logic circuit LG11 and/or the input path selection circuit IRSL, the logic value of the output signal fetched and held in the input F/F circuit FFI1-1 synchronously with a change in the internal test clock signal TSCLK varies. That is, according to the delay time in the input path, the logic value held in the input F/F circuit FFI1-1 varies.

In the operation timing test, to output a result held in the input F/F circuit (input-stage F/F circuit), according to the test selection control signal T-CTLi, the selector MUX3 of the input-stage test circuit TSI-1 selects the input terminal N2, and the selector MUX4 selects the input terminal N2. Consequently, the data input terminal D of the input F/F circuit FFI1-1 is electrically coupled to the input terminal Pdi, and the data output terminal Q of the input F/F circuit FFI1-1 is electrically coupled to the data input terminal D of the input F/F circuit FFI1-2 at the next stage.

That is, the input F/F circuits FFI1-1, FFI1-2, FFI2-1, FFI2-2, and FFI3-1 illustrated in FIG. 4 are coupled in series between the input terminal Pdi and the output terminal Pdo to form a shift register. Since the internal test clock signal TSCLK is supplied as a sync clock signal to the clock input terminal CK in each of the input F/F circuits, the shift clock signal of the shift register becomes the internal test clock signal TSCLK, and the logic value of the output signal held in each input F/F circuit is sequentially output from the output terminal Pdo synchronously with the change in the internal test clock signal TSCLK. In such a manner, the result of the operation timing test can be obtained.

In the operation timing test, for example, in the case where the input F/F circuit FFI1-1 is not designated, the selectors MUX3 and MUX4 in the corresponding input-stage test circuit TSI-1 may select an arbitrary input terminal. However, according to the test selection control signal T-CTLi, for example, in a manner similar to the case of designating the circuit, the selector MUX4 may select the input terminal N2 and the selector MUX3 may select the input terminal N1.

Referring to FIGS. 1 to 4, it has been described that the input path test circuit TST-I and the output path test circuit TST-O generate the input path selection signal and the output path selection signal, respectively, in accordance with the external test control signal T-CTL. However, the invention is not limited to the case. For example, each of the input path test circuit TST-I and the output path test circuit TST-O may generate the input path selection signal and the output path selection signal, respectively, in accordance with the external test control signal T-CTL and the test signal T-DI. In this case, the input path test circuit TST-I may set the input path into the selection state according to the test control signal T-CTL and designate an input path to be selected in accordance with the value of the test signal T-DI. Similarly, the output path test circuit TST-O may set the output path into the selection state according to the test control signal T-CTL and designate an output path to be selected in accordance with the value of the test signal T-DI.

### Operation Timing Test

### Operation Timing Test in Manufacture Process of Semiconductor Device

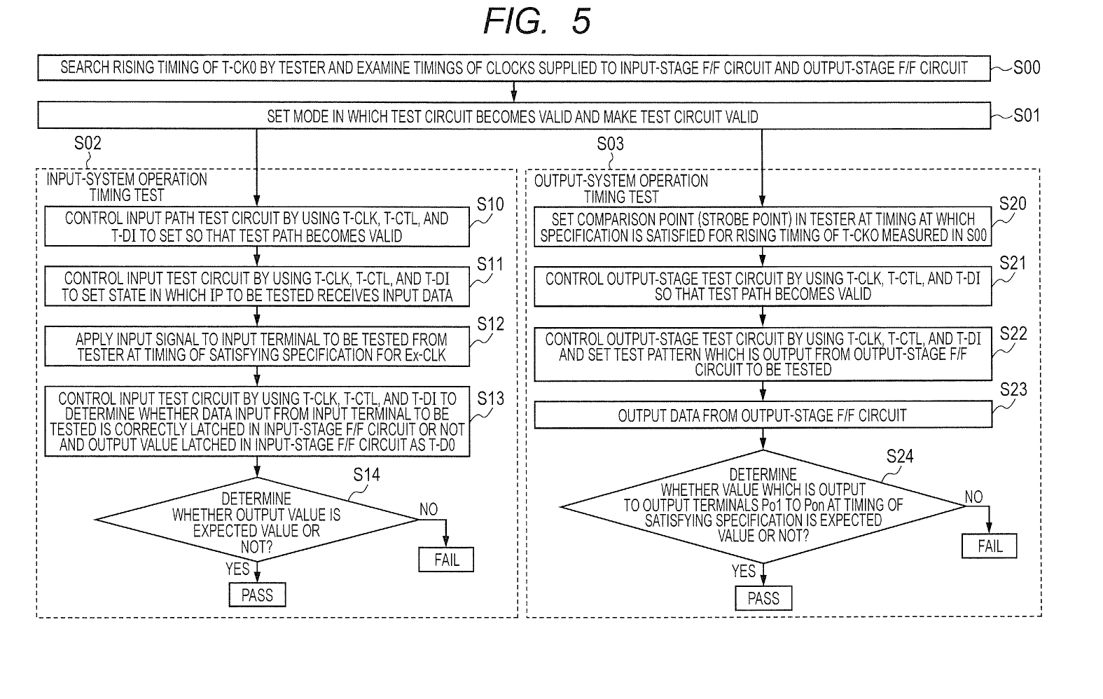

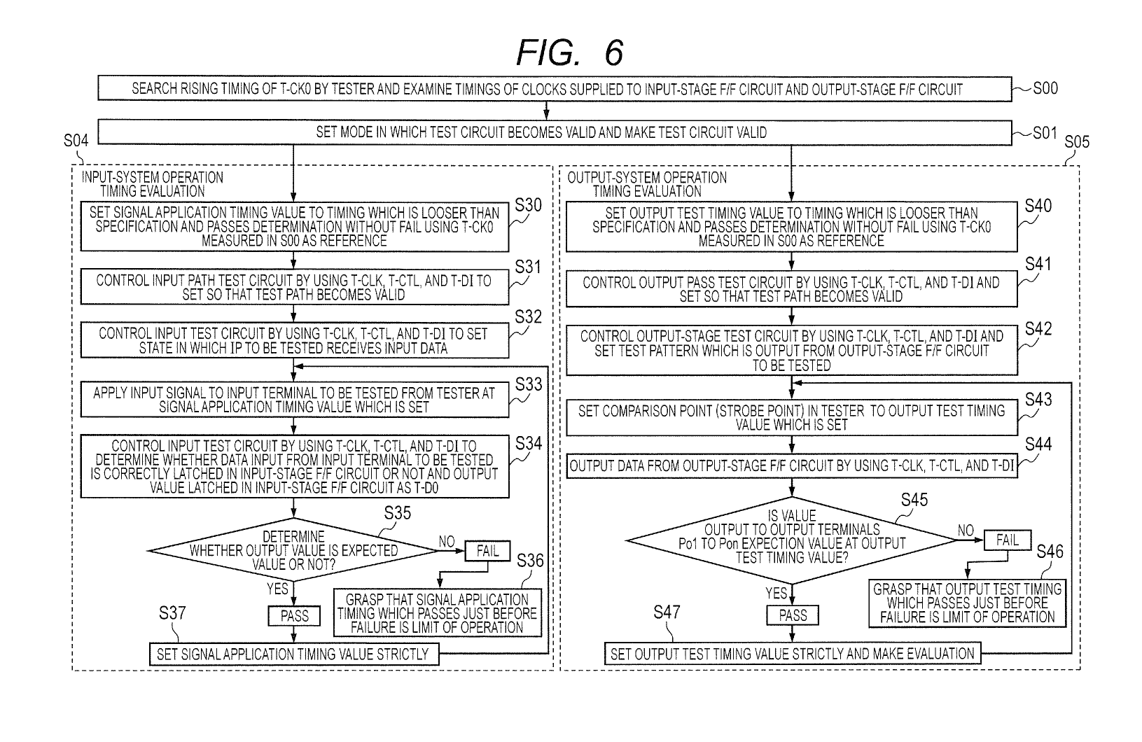

Next, the operation of the operation timing test will be described with reference to FIGS. 5 and 6. FIG. 5 is a flowchart diagram illustrating operations of an operation timing test to be executed in a method of manufacturing a semiconductor device. The method of manufacturing a semiconductor device includes a manufacture process of manufacturing a semiconductor device and a test process of testing a semiconductor device manufactured in the manufacture process. In the test process, a test circuit or a test device (tester) is coupled to the manufactured semiconductor device to test the semiconductor device. In the test process, a plurality of tests including the operation timing test are executed. In FIG. 5, only the operation timing test in the tests performed in the test process is specifically illustrated.

The operation timing test includes a step of an input-system operation timing test executed on the input system, a step of an output-system operation timing test executed on the output system, and a common step common to the input-system operation timing test and the output-system operation timing test. Referring to FIGS. 1 to 5, the operation timing test will be described. In FIG. 5, steps S00 and S01 are common steps, step S02 is a step of the input-system operation timing test, and step S03 is a step of the output-system operation timing test.

The semiconductor device is coupled to a tester and step S00 is executed. In the step S00, the external test clock signal T-CLK is supplied from the tester to the input terminal Pck, and the test clock signal T-CKO output from the output terminal Pco is examined. That is, a timing at which the test clock signal T-CKO rises synchronously with the rising of the external test clock signal T-CLK is examined by the tester. Consequently, the timing of the clock signal (the sync clock signal at the time of a test) supplied to the clock input terminal CK of the input-stage F/F circuit and the output-stage F/F circuit is examined and grasped.

In FIGS. 1 to 4, it is illustrated that the input terminals Pdi, Pct, Pck, and Pet and the output terminals Pco and Pdo are provided independently of the semiconductor device CHP. The input terminals and the output terminals may be also commonly used as other input terminals or output terminals provided for the semiconductor device CHP. By using the terminals commonly, the number of terminals of the semiconductor device CHP can be reduced or used effectively. In the case of effectively using the terminals, the number of the terminals of the semiconductor device CHP can be reduced or effectively used. In the case of commonly using the input and output terminals as described above, for example, the semiconductor chip CHP has a test mode of making the test circuits (the input path test circuit, the output path test circuit, the input-stage test circuit, and the output-stage test circuit) effective and a process mode of operating the process units such as the processor CPU. In step S01, the semiconductor device CHP is set in the mode (test mode) of making the test circuit valid and it is set so that the terminals commonly used function as the input terminals Pdi, Pct, Pck, and Pet and the output terminals Pco and Pdo. In the case where the input-system operation timing test is designated in the test mode, the input path test circuit and the input-stage test circuit out of the input path test circuit, the output path test circuit, the input-stage test circuit, and the output-stage test circuit operate. On the other hand, in the case where the output-system operation timing test is designated, out of the input path test circuit, the output path test circuit, the input-stage test circuit, and the output-stage test circuit, the output path test circuit and the output-stage test circuit operate.

Next, the operation of the input-system operation timing test will be described. Step S02 of the input-system operation timing test has steps S10 to S14. In the input-system operation timing test, first, step S10 is executed. In step S10, by the input path test circuit TST-I, the input path selection signal is generated. That is, from the tester, the external test clock signal T-CLK, the test signal T-DI, and the external test control signal T-CTL are supplied to the input terminals Pck, Pct, and Pdi. At this time, the test control signal T-CTL supplied by the tester is a control signal expressing an input path selection state of selecting an input path. The tester supplies designation information of designating an input path to be tested. By setting the test control signal T-CTL as a control signal expressing the input path selection state, the input path test circuit TST-I enters an operable state and, according to the test signal T-DI supplied at this time, generates the input path selection signal. The input path selection signal is supplied to the input path selection circuit IRSL and a test path to be tested is made valid. At this time, the input path selection control circuit RSC-I is made invalid and the input path determined by the user is made invalid.

In step S11, the tester supplies the external test clock signal T-CLK, the test signal T-DI, and the test control signal T-CTL to the input terminals Pck, Pct, and Pdi. The tester outputs, as the test control signal T-CTL, a control signal so that the selector MUX4 in the input-stage test circuits TSI-1 to TSI-3 selects the internal test clock signal TSCLK and the selector MUX3 selects an output signal from the logic circuit. The tester supplies, as the test signal T-DI, a designation signal of designating an input-stage F/F circuit to be tested. On the basis of the test signal T-DI and the test control signal T-CTL from the tester, the test control circuit described with reference to FIG. 3 generates the test selection control signal T-CTLi. In such a manner, a function unit including a logic circuit (for example, the logic circuit LG11) supplying an output signal to the designated input-stage F/F circuit becomes a function unit to be tested. That is, the input-stage F/F circuit included in the function unit (IP) to be tested becomes capable of receiving (fetching) input data.

In step S12, the tester applies an input signal to the input terminals Pi1 to Pin to be tested at a timing of satisfying the specification of the semiconductor device CHP for the external operation clock signal Ex-CLK. Specifically, the input signal is supplied to the target input terminal at a timing within time specified in the specifications with respect to a change in the external operation clock signal Ex-CLK. The input signal at this time corresponds to the test pattern.

In step S13, the tester supplies the external test clock signal T-CLK, the test control signal T-CTL, and the test signal T-DL to the input terminals Pck, Pct, and Pdi to determine whether data corresponding to the input signal applied to the input terminal to be tested is correctly held (latched) by the input-stage F/F circuit or not. At this time, the tester outputs, as the test control signal T-CTL, a control signal so that the selector MUX4 in each of the input-stage test circuits TSI-1 to TSI-3 selects the input terminal and the selector MUX3 selects the input terminal N1. By the signal, the input-stage F/F circuits are coupled in series and a shift register is configured. By changing the external test clock signal T-CLK, the values held (latched) in the input-stage F/F circuits are sequentially output from the output terminal Pdo. In step S13, the tester supplies the test signal T-DI as a shift input of the shift register.

In step S14, the tester determines whether the value (output value) output from the output terminal Pdo in step S13 matches an expectation value for the test pattern or not. When the values match, it is determined that the operation timing test regarding the target input terminal and the target function unit (IP) is successful (“PASS”). When the values do not match, it is determined as failure (“FAIL”).

Next, the operation of the output-system operation timing test will be described. Step S03 of the output-system operation timing test includes steps S20 to S24. First, in step S20, the tester sets a comparison point (strobe point) of comparing output signals in the output terminals Po1 to Pon at the timing of satisfying the specification of the semiconductor device CHP with respect to the rising timing of the external test clock signal T-CKO examined in step S00. Specifically, within time in which the specification is satisfied after the external test clock signal T-CKO rises, the timing (comparison point) of comparing the signals of the output terminals Po1 to Pon with the expectation value for the test pattern is determined.

In step S21, the tester supplies the external test clock signal T-CTK, the test control signal T-CTL, and the test signal T-DI to the input terminals Pck, Pct, and Pdi. At this time, the test control signal T-CTL supplied from the tester is a control signal expressing an output path selection state of selecting the output path. The tester supplies designation information of designating the output path to be tested as the test signal T-DI. By setting the test control signal T-CTL as a control signal expressing the output path selection state, the output path test circuit TST-O enters an operable state and generates an output path selection signal in accordance with the test signal T-DI supplied at that time. The output path selection signal is supplied to the output path selection circuit ORSL and the test path to be tested is made valid. At this time, the output path selection control circuit RSC-O is made invalid, and the output path determined by the user is made invalid.

In step S22, the tester supplies the external test clock signal T-CLK, the test signal T-DI, and the test control signal T-CTL to the input terminals Pck, Pct, and Pdi. At this time, the tester outputs, as the test control signal T-CTL, a control signal so that the selector MUX4 in the output-stage test circuits TSO-1 to TSO-3 selects the internal test clock signal TSCLK and the selector MUX3 selects the test signal T-DI or an output signal from the output-stage F/F circuit (output F/F circuit) of the front stage. At this time, the tester supplies a designation signal of designating an output-stage F/F circuit to be tested as the test signal T-DI. On the basis of the test signal T-DI and the test control signal T-CTL from the tester, the test control circuit described with reference to FIG. 3 generates the test selection control signal T-CTLi. In such a manner, the test signal T-DI is sequentially supplied to the output-stage F/F circuit designated as a test target. A test pattern is configured by the test signal T-DI at this time. As a result, the test pattern is set in the output-stage F/F circuit to be tested.

In step S23, the test pattern is output from the output-stage F/F circuits FFO1 to FFOp. In step S24, the tester determines whether the values of the output terminals Po1 to Pon are expectation values corresponding to the test pattern or not at the comparison point set in step S20. When the value matches the expectation value, it is determined that the operation timing test regarding the designated output-stage F/F circuit and the output terminal is successful (“PASS”). When the values do not match, it is determined as failure (“FAIL”).

### Operation Timing Test in Evaluation of Semiconductor Device

Also at the time of evaluating the performance of the semiconductor device, the operation timing test is performed. FIG. 6 is a flowchart diagram illustrating operations of an operation timing test which is executed at the time of evaluating the semiconductor device CHP. In the diagram, steps SOO and S01 are the same as the steps S00 and S01 illustrated in FIG. 5. That is, the common steps in FIG. 5 and those in FIG. 6 are the same, so that the description will not be repeated. An input-system operation timing test (input-system operation timing evaluation) which is executed at the time of evaluating the semiconductor device CHP is indicated as step S04 in FIG. 6, and an output-system operation timing test (output-system operation timing evaluation) is indicated as step S05.

The step S04 of the input-system operation timing evaluation includes steps S30 to S37. In the step S30, the tester sets a signal application timing of applying a signal to the input terminals Pi1 to Pin to a timing which is looser than the specification of the semiconductor device CHP and passes the determination (“PASS”) without fail using, as a reference, the rising timing of the external test clock signal T-CKO examined in step S00.

Since step S31 is the same as step S10 and step S32 is the same as step S11, the steps S31 and S32 will not described. Step S33 is similar to step S12 but the timing of applying the input signal from the tester to the input terminals Pi1 to Pin to be tested is the signal application timing which is set in step S30. Steps S34 and S35 are the same as the steps S13 and S14, so that the description will not be repeated.

In the case of mismatch in step S35, the tester determines as failure (“FAIL”) and executes step S36. In the case of match, the tester determines as success (“PASS”) and executes step S37.

In step S37, the value of the signal application timing is set strictly. After that, steps S33 to S35 are executed again. Steps S33 to S35 and step S37 are repeated until mismatch is determined in step S35. In step S36, the tester grasps the value of a signal application timing which passed (“PASS”) just before failure (“FAIL”) as a value of a limit of operation for the input signal.

Step S05 of the output-system operation timing evaluation includes steps S40 to S47. In step S40, the tester sets a value of a timing of testing output signals (output test timing value) output from the output terminals Pot to Pon to a timing which is looser than the specification of the semiconductor device CHP and passes the determination (“PASS”) without fail using, as a reference, the rising timing of the external test clock signal T-CKO examined in step S00.

Since step S41 is the same as step S21 and step S42 is the same as step S22, steps S41 and S42 will not described. Step S43 is similar to step S20 but the comparison point (strobe point) in the tester is the output test timing value which is set in step S40. Step S44 is the same as step S23, so that the description will not be repeated.

In step S45, at the time of the output test timing value, the tester determines whether the value of the output signal output to the output terminals Pol to Pon matches an expectation value for the test pattern or not. In the case of mismatch in the determination of step S45, tester determines as failure (“FAIL”) and executes step S46. In the case of match, the tester determines as success (“PASS”) and executes step S47.

In step S47, the value of the output test timing is set strictly. After that, steps S43 to S45 are executed again. Steps S43 to S45 and step S47 are repeated until mismatch is determined in step S45. In step S46, the tester grasps the value of the output test timing which passed (“PASS”) just before failure (“FAIL”) as a value of a limit of operation for the output signal.

According to the first embodiment, using the test clock signal output from the output terminal Pco as a reference, the operation timing test can be executed. Consequently, a semiconductor device CHP capable of easily performing an operation timing test even the number of F/F circuits provided in the semiconductor device CHP increases can be provided.

According to the first embodiment, without grasping the function of a processing unit, a test pattern for an operation timing can be generated. By supplying a test pattern from the tester to the semiconductor device, the operation timing test can be executed. Consequently, even when the configuration of a processor as a component of a process unit changes, a test pattern can be generated. Further, since a test pattern is not generated by a program of a processor in the semiconductor device, it is unnecessary to verify a program.

### Modification

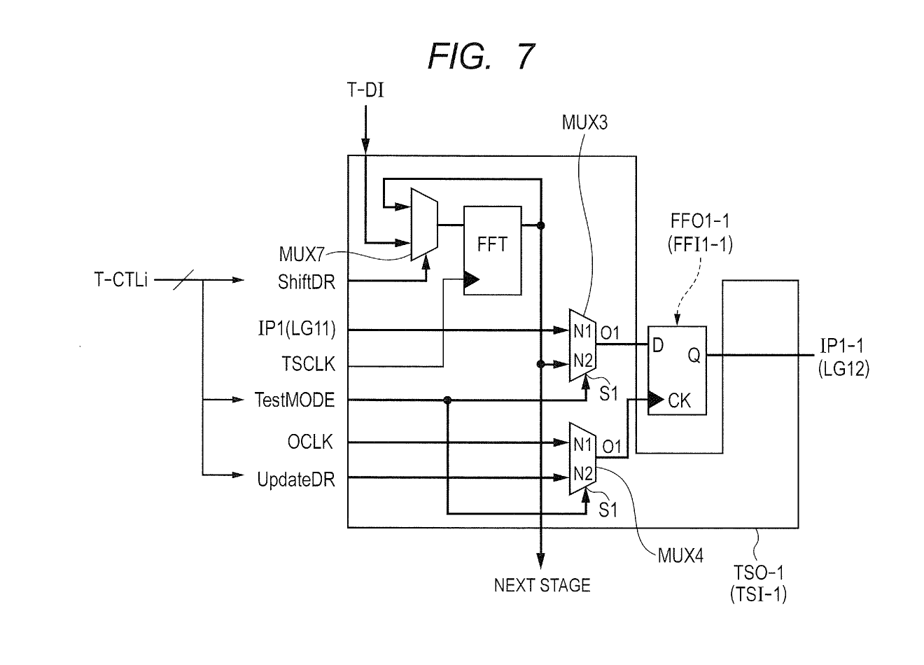

FIG. 7 is a block diagram illustrating the configuration of a modification of an output-stage test circuit ISO or an input-stage test circuit TSI. The configuration illustrated in the diagram can be used as the output-stage test circuit ISO or the input-stage test circuit TSI like the test circuit illustrated in FIG. 3. First, the case of using the configuration of FIG. 7 as an output-stage test circuit will be described. In FIG. 7, the configuration of the output-stage test circuit ISO-1 is illustrated as a representative of the output-stage test circuits TSO.

In FIG. 7, like in FIG. 3, FFO1-1 indicates an output F/F circuit and ISO-1 indicates an output-stage test circuit. Since the configuration of the output F/F circuit FFO1-1 is the same as that in FIG. 3, the description will not be repeated.

Like in FIG. 3, the output-stage test circuit ISO-1 has the selectors MUX3 and MUX4, the output signal IP1 and the internal operation clock signal OCLK are supplied to the input terminals N1 of the selectors MUX3 and MUX4, and the output terminals O1 are coupled to the data input terminal D and the clock input terminal CK of the output F/F circuit FFO1-1. Moreover, the output-stage test circuit ISO-1 has a selector MUX7 and an F/F circuit FFT.

The output-stage test circuit ISO-1 in the modification is configured as a test data register defined in IEEE (i triple e) 1149.1 (boundary scan). In this case, the test selection control signal T-CTLi (i=1 to p) is comprised of a testMODE signal, ShiftDR signal, and UpdateDR signal. The ShiftDR signal is supplied to the selection terminal of the selector MUX7, the data output terminal of the selector MUX7 is coupled to the data input terminal of the F/F circuit FFT, the data output terminal of the F/F circuit FFT is coupled to one of input terminals of the selector MUX7, and the test signal T-DI is supplied to the other input terminal of the selector MUX7. To the clock input terminal of the F/F circuit FFT, the internal test clock signal TSCLK is supplied. By coupling the other input terminal of the selector MUX7 and the data input terminal of the F/F circuit FFT by the ShiftDR signal, the F/F circuits FFT in a plurality of output-stage test circuits ISO-1 to TSO-p are coupled in series to form a shift register dedicated to a test.

In the case of setting a value desired to be set (test pattern) in the output F/F circuit FFOI-1, the shift register dedicated to a test is used. That is, the test signal T-DI is sequentially transferred in the shift register, and a value desired to be set is set in the F/F circuit FFT. At this time, by the TestMODE signal, the selectors MUX3 and MUX4 select the input terminal N2. Consequently, the UpdateDR signal is supplied as a sync signal of the output F/F circuit FFO1-1 to the clock input terminal CK, and the value desired to be set is supplied to the data input terminal D of the output F/F circuit FFO1-1. As a result, in the operation timing test, the value desired to be set is fetched in the output F/F circuit FFO1-1 synchronously with the UpdateDR signal. Therefore, a function similar to that of the output-stage test circuit illustrated in FIG. 3 can be achieved.

In the case of using the configuration illustrated in FIG. 7 as the input-stage test circuit TSI-1, like in FIG. 3, the reference numerals are changed to the reference numerals indicated in parentheses. Also in the case of using the configuration as the input-stage test circuit TSI-1, by performing a control in a manner similar to that described in FIG. 3, in the operation timing test, an output signal from the logic circuit LG11 can be fetched in the input F/F circuit FFI1-1 synchronously with the UpdateDR signal. In this case, the logic values of output signals fetched in the input F/F circuits can be output, for example, in parallel from the semiconductor device CHP.

The above-described output-stage F/F circuits FFO1 (the output F/F circuits FFO1-1 and FFO1-2), FFO2 (the output F/F circuits FFO2-1 and FFO2-2), and FFO3 (FFO3-1) are, for example, final-output-stage F/F circuits of the corresponding function units IP1, IP2, and IP3. The above-described input-stage F/F circuits FFI1 (the input F/F circuits FFI1-1 and FFI1-n), FFI2 (the input F/F circuits FFI2-1 and FFI2-n), and FFI3 (FFI3-1) are, for example, first-input-stage F/F circuits of the corresponding function units IP4, IP5, and IP6. That is, as the above-described output-stage F/F circuits FFO1 to FFO3 and the input-stage F/F circuits FFI1 to FFI3, the F/F circuits included in a function unit determined by the user are used. Alternatively, to the function unit, the above-described output-stage F/F circuits FFO1 to FFO3 and the input-stage F/F circuits FFI1 to FFI3 may be added.

### Second Embodiment

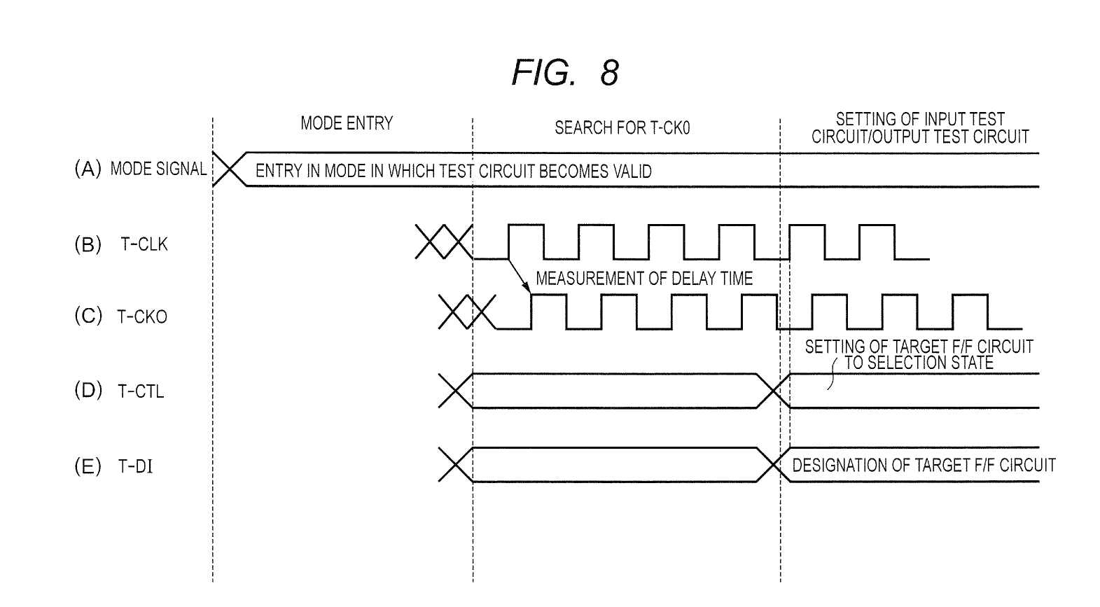

FIGS. 8 to 10 are waveform charts illustrating operations of an operation timing test according to a second embodiment. The configuration of the semiconductor device CHP is the same as that described in the first embodiment. In FIGS. 8 to 10, the horizontal axis indicates time.

In the operations of the operation timing test described with reference to FIGS. 5 and 6 and, similarly, also in the operations of the operation timing test in the second embodiment, the operation timing test has common steps, steps of the input-system operation timing test, and steps of the output-system operation timing test. Obviously, in a single operation timing test, both of the steps of the input-system operation timing test and the steps of the output-system operation timing test may not be executed.

### Common Operations

First, operations (common operations) related to the common steps will be described with reference to FIG. 8. In FIG. 8, (A) indicates the waveform of a mode signal designating a mode to the semiconductor device CHP, (B) indicates the waveform of the external test clock signal T-CLK, (C) indicates the waveform of the external test clock signal T-CKO, (D) indicates the waveform of the test control signal T-CTL, and (E) indicates the waveform of the test signal T-DI. Those signals are generated by the tester in a test process.

First, as illustrated in (A) in FIG. 8, the tester changes the mode signal and enters a mode (test mode) that test circuits (the input path test circuit, the output path test circuit, the input-stage test circuit, and the output-stage test circuit) become valid. By entering the mode in which the test circuits become valid, in the semiconductor device CHP, terminals also serving as terminals related to a test are changed to become input and output terminals related to a test as illustrated in FIG. 1.

After the entry to the mode in which the test circuits become valid is made, the external test clock signal T-CKO is searched. In the search of the external test clock signal T-CKO, as illustrated in (B) in FIG. 8, the tester changes the external test clock signal T-CLK. By the change in the external test clock signal T-CLK, the test clock signal T-CKO output from the output terminal Pco also changes. The tester inputs the test clock signal T-CKO and measures the time difference between the external test clock signal T-CLK and the test clock signal T-CKO, that is, delay time.

After the delay time of the test clock signal T-CKO is measured, the tester sets the input-stage test circuit TSI and/or the output-stage test circuit TSO. By the setting of the input-stage test circuit TSI and/or the output-stage test circuit TSO, the input-stage F/F circuit and/or the output-stage F/F circuit used for an operation timing test are selected (designated) as targets by the tester.

Specifically, in the setting of the input-stage test circuit TSI and/or the output-stage test circuit TSO, the tester supplies the test control signal T-CTL as a control signal of setting a target F/F circuit (input-stage F/F circuit, output-stage F/F circuit) into a selection state synchronously with the external test clock signal T-CLK ((D) in FIG. 8). At this time, the tester supplies a designation signal designating a target F/F circuit as the test signal T-DI synchronously with the external test clock signal T-CLK ((E) in FIG. 8). The test control circuit described in FIG. 3 supplies, as the test selection control signal, a control signal for setting the target F/F circuit designated by the designation signal designating the target F/F circuit into a selection state. In such a manner, the target F/F circuit designated by the designation signal from the F/F circuits is set in the selection state.

After that, the output-system operation timing test and/or the input-system operation timing test are/is performed.

### Output-System Operation Timing Test

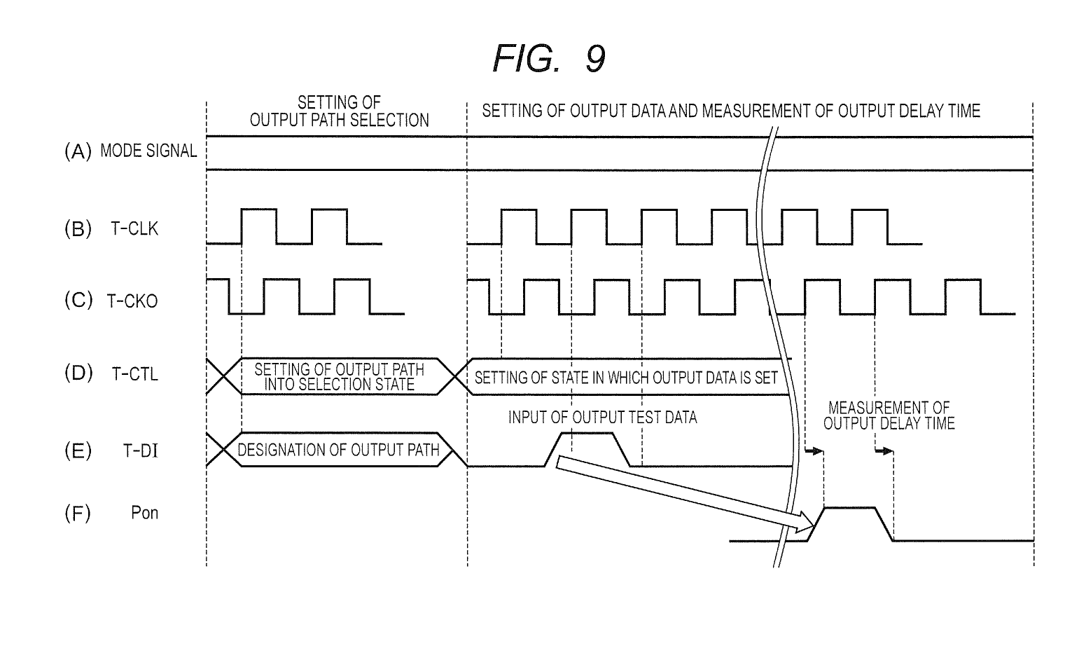

Next, the operations of the output-system operation timing test will be described with reference to FIG. 9. (A) to (E) in FIG. 9 indicate, like (A) to (E) in FIG. 8, the waveform of the mode signal, the waveform of the external test clock signal T-CLK, the waveform of the test clock signal T-CKO, the waveform of the test control signal T-CTL, and the waveform of the test signal T-DI, and illustrate changes in the waveforms after (A) to (E) in FIG. 8.

The waveform of the mode signal indicated in (A) in FIG. 9 maintains, although not limited, the mode in which the test circuits are valid. The tester supplies, as the test control signal T-CTL, the control signal of setting the output path into the selection state synchronously with the external test clock signal T-CLK and supplies the designation signal designating the output path as the test signal T-DI ((D) and (E) in FIG. 9). In such a manner, setting of the output path selection is made. Specifically, the output path test circuit TST-O generates the output path selection signal on the basis of the test signal T-DI and the test control signal T-CTL at this time and supplies it to the output path selection circuit ORSL. In the output path selection circuit ORSL, the connection state of the selector is determined according to the output path selection signal, and the output path designated by the designation signal designating an output path is formed between the function unit and the output terminals Po1 to Pon.

Next, the tester supplies, as the test control signal T-CTL, a control signal of setting a state of setting output data in the output-stage F/F circuits FFO1 to FFOp synchronously with the external test clock signal T-CLK ((D) in FIG. 9). After that, the tester supplies, as the test signal T-DI, the output data to be set synchronously with the external test clock signal T-CLK. By the test control signal T-CTL at this time, the output-stage F/F circuits are coupled in series to form a shift register. To the shift register, the test signal T-DI is supplied. The test signal T-DI shifts in the shift register using the internal test clock signal TSCLK as a shift clock signal and is held in each of the output-stage F/F circuits forming the shift register.

After that, at a predetermined timing (comparison point), the tester detects a change in the output signal in the output terminals Po1 to Pon. (F) in FIG. 9 indicates a change in an output signal in the output terminal Pon in the output terminals Pol to Pon. Using the rising timing of the test clock signal T-CKO output from the output terminal Pco of the semiconductor device CHP as a reference, the tester obtains, as output delay time, the time difference of the rising timing and/or the trailing timing of the output signal in the output terminal Pon. The output delay times of output signals in the remaining output terminals are also similarly obtained. In such a manner, setting of the output data and measurement of the output delay time are performed.

In the common step illustrated in FIG. 8, the delay time between the external test clock signal T-CLK supplied to the semiconductor device CHP and the test clock T-CKO output from the semiconductor device CHP is obtained, so that the tester can obtain delay time of the signal change in each of the output terminals Po1 to Pon using the external test clock signal T-CLK as a reference. The tester can determine whether the value of the output signal matches the expectation value for the test pattern or not at the comparison point.

### Input-System Operation Timing Test

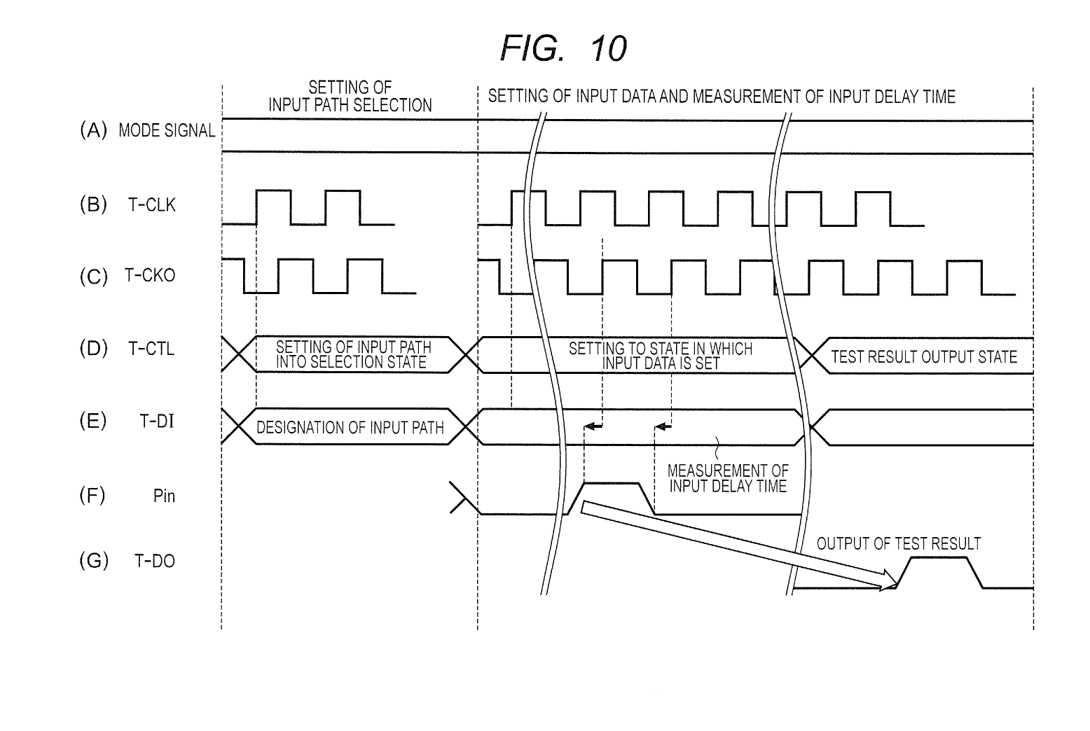

The operations of the input-system operation timing test will be described with reference to FIG. 10. (A) to (E) in FIG. 10 indicate, like (A) to (E) in FIG. 8, the waveform of the mode signal, the waveform of the external test clock signal T-CLK, the waveform of the test clock signal T-CKO, the waveform of the test control signal T-CTL, and the waveform of the test signal T-DI, and illustrate changes in the waveforms after (A) to (E) in FIG. 8.

The waveform of the mode signal indicated in (A) in FIG. 10 maintains, although not limited, the mode in which the test circuits are valid. The tester supplies, as the test control signal T-CTL, the control signal of setting the input path into the selection state synchronously with the external test clock signal T-CLK and supplies the designation signal designating the input path as the test signal T-DI ((D) and (E) in FIG. 10). In such a manner, setting of the input path selection is made. Specifically, the input path test circuit TST-I generates the input path selection signal on the basis of the test signal T-DI and the test control signal T-CTL at this time and supplies it to the input path selection circuit IRSL. In the input path selection circuit IRSL, the connection state of the selector is determined according to the input path selection signal, and the input path designated by the designation signal designating an input path is formed between the function unit and the input terminals Pi1 to Pin.

Next, the tester supplies, as the test control signal T-CTL, a control signal of setting a state of setting input data in the input-stage F/F circuits FFI1 to FFIp synchronously with the external test clock signal T-CLK ((D) in FIG. 10). After that, the tester supplies the input signal (input data) to the input terminals Pi1 to Pin. In FIG. 10, the waveform at the time of supplying an input signal to the input terminal Pin is illustrated as (F) as an example. Using the rising timing of the test clock signal T-CKO output from the output terminal Pco of the semiconductor device CHP as a reference, the tester measures the time difference of the rising timing and/or the trailing timing of the input signal as input delay time.

After predetermined time, the tester supplies, as the test control signal T-CTL, the control signal indicating a state of outputting a test result to the semiconductor device CHP. By the operation, in the semiconductor device CHP, the input-stage F/F circuits FFI1 to FFIp are coupled in series to form a shift register. The internal test clock signal TSCLK is used as a shift clock signal, and the values of the shift register are sequentially output as the output signal T-DO from the output terminal Pdo. The output signal T-DO becomes the test result output.

The tester uses the input data supplied to the input terminals Pi1 to Pin as a test pattern and determines whether the output signal T-DO matches an expectation value corresponding to the test pattern or not. In the case where the values match, input delay time using the test clock signal T-CLK as a reference is obtained by delay time preliminarily measured in FIG. 8 and input delay time using the test clock signal T-CKO as a reference.

In the first and second embodiments, the output-system operation timing test and the input-system operation timing test may be executed substantially at the same time or may be executed separately. The terminals used for the operation timing tests, for example, the terminals Pdi, Pck, Pdo, and the like may be set in two systems for the output-system operation timing test and the input-system operation timing test, and the terminals of each of the systems may be provided for the semiconductor device CHP.

### Third Embodiment

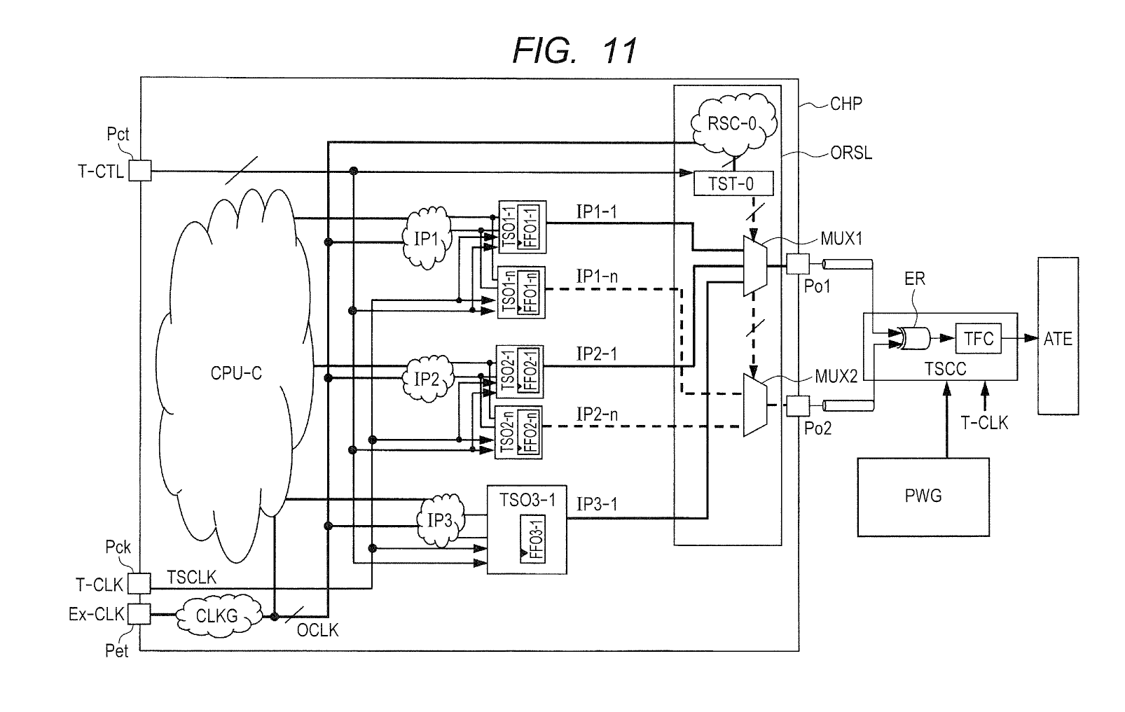

FIG. 11 is a block diagram illustrating the configuration of a semiconductor device CHP according to a third embodiment. In FIG. 11, the output system of the semiconductor device CHP is mainly illustrated, and the configuration is similar to that of the semiconductor device CHP illustrated in FIG. 2. The points different from the configuration illustrated in FIG. 2 will be mainly described here. The control unit CPU-C as a component of the processor CPU and the function units IP1 to IP3 are the same, and the clock generation circuit CLKG, the selectors MUX1 and MUX2, and the output path selection control circuit RSC-O are also the same. Consequently, the description of those components will not be repeated except for the case where the description is necessary for convenience of the description.

In the third embodiment, the semiconductor device CHP is not provided with the input terminal Pdi and the output terminals Pco and Pdo. The configuration of the output-stage test circuit is different from that of the output-stage test circuit illustrated in FIG. 2, and the configuration of the output path test circuit is also different from that of the output path test circuit illustrated in the diagram.

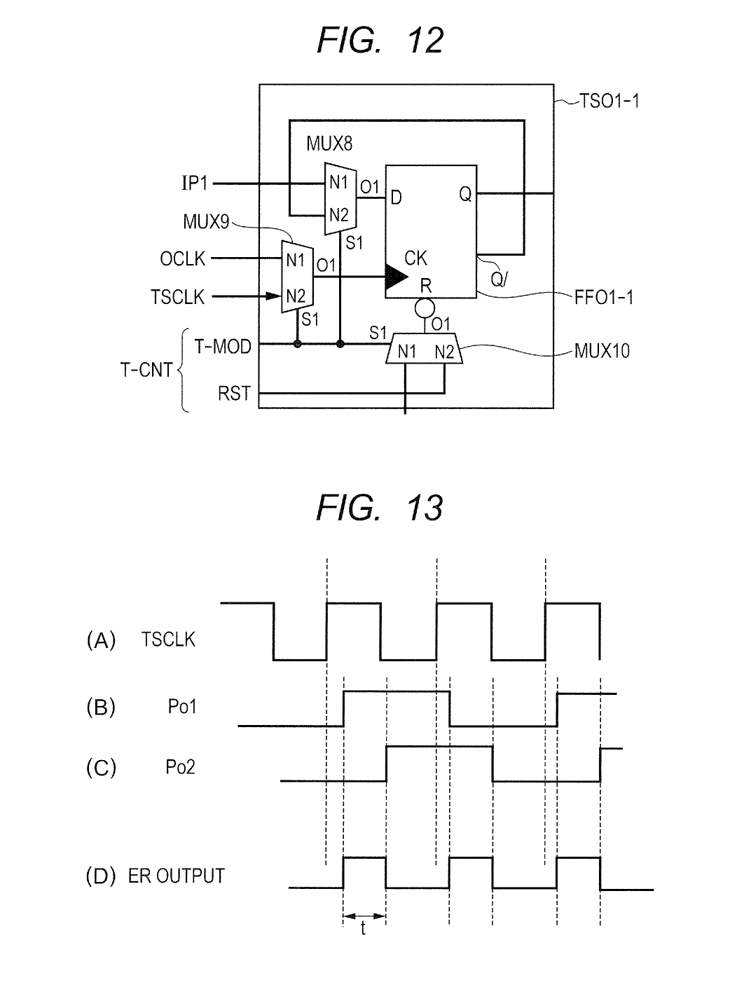

In FIG. 11, FFO1-1 to FFO1-n, FFO2-1 to FFO2-n, and FFO3-1 indicate output-stage F/F circuits, and TSO1-1 to TSO1-n, TSO2-1 to TSO2-n, and TSO3-1 indicate output-stage test circuits (first selection circuits). The output-stage F/F circuits FFO1-1 to FFO1-n, FFO2-1 to FFO2-n, and FFO3-1 have the same configuration, and the output-stage test circuits TSO1-1 to TSO1-n, TSO2-1 to TSO2-n, and TSO3-1 also have the same configuration. An example of the configurations and the operations of the output-stage test circuit and the output-stage F/F circuit will be described later with reference to FIGS. 12 and 13. They will be briefly described now.

Although not limited, in the third embodiment, the output-stage test circuit corresponds to the output-stage F/F circuit on a one-to-one basis. The output-stage test circuit TSO1-1 will be described as an example. The output-stage test circuit TSO1-1 corresponds to the output-stage F/F circuit FFO1-1. The output-stage test circuit TSO1-1 receives the test control signal T-CTL supplied to the input terminal Pct, the internal operation clock signal OCLK, the internal test clock signal TSCLK, and an output signal from the function unit IP1 and changes a sync clock signal supplied to the corresponding output-stage F/F circuit FFO1-1 and the supplied input signal between the normal operation and the operation timing test.

Specifically, in the normal operation, the output-stage test circuit TSO1-1 selects the internal operation clock signal OCLK as a sync clock signal of the output-stage F/F circuit FFO1-1 and supplies it. In the normal operation, the output-stage test circuit TSO1-1 selects the output signal from the function unit IP1 as an input signal of the output-stage F/F circuit FFO1-1 and supplies it. Consequently, in the normal operation, the output-stage F/F circuit FFO1-1 fetches an output signal from the function unit IP1 synchronously with the internal operation clock signal OCLK, and the output signal IP1-1 of the logic value corresponding to the fetched output signal is transmitted from the output-stage test circuit TSO1-1 to the output path selection circuit ORSL.

In contrast, in the operation timing test, the internal test clock signal TSCLK is selected as a sync clock signal of the output-stage F/F circuit FFO1-1 and supplied. In the operation timing test, by using the corresponding output-stage F/F circuit FFO1-1, a test signal synchronized with the internal test clock signal TSCLK is generated and is transmitted as the output signal IP1-1 to the output path selection circuit ORSL.

The remaining output-stage test circuit and the output-stage F/F circuit also perform similar operations. As a result, in the normal operation, output signals from the function units IP1 to IP3 are fetched in the output-stage F/F circuits FFO1-1 to FFO1-n, FFO2-1 to FFO2-n, and FFO3-1 synchronously with the internal operation clock signal OCLK and transmitted as the output signals IP1-1 to IP1-n, IP2-1 to IP2-n, and IP3-1 to the output path selection circuit ORSL. In the operation timing test, the signals synchronized with the internal test clock signal TSCLK are transmitted as output signals IP1-1 to IP1-n, IP2-1 to IP2-n, and IP3-1 to the output path selection circuit ORSL.

In the operation timing test, the output path test circuit TST-0 (second selection circuit) receives the test control signal T-CTL and generates the output path selection control signal. In a manner similar to the first embodiment, in the normal operation, the output path selection control circuit RSC-O generates an output path selection control signal so that an output path determined by the user is formed. In the operation timing test, the output path selection control circuit RSC-O is made invalid, the selectors MUX1 and MUX2 are controlled by the output path selection control signal generated by the output path test circuit TST-O, and an output path is determined. In the third embodiment, since the test input signal T-DI is not supplied, the output path cannot be designated by the test input signal T-DI. However, since the test control signal T-CTL is formed by a plurality of signals, for example, by signals as a part of the signals forming the test control signal T-CTL, the output path may be designated.

In the third embodiment, in the operation timing test, the signals generated by the output-stage test circuits TSO1-1 to TSO1-n, TSO2-1 to TSO2-n, and TSO3-1 are transmitted as the output signals IP1-1 to IP1-n, IP2-1 to IP2-n, and IP3-1 to the output terminals Po1 and Po2 via signal lines (not illustrated) and selectors. In this case, the signals generated by the output-stage test circuits become clock signals synchronized with the internal test clock signal TSCLK.

In the embodiment, by measuring the time difference between the clock signals transmitted to the output terminals Pol and Po2, the operation timing test is executed. Specifically, when the time difference between the clock signals transmitted to the output terminals is longer than predetermined time, it is determined that the operation timing test fails (“FAIL”). When the time difference is shorter than the predetermined time, it is determined that the operation timing test succeeds (“PASS”). In such a manner, it becomes unnecessary to generate a clock signal as a reference by the semiconductor device CHP and also it becomes unnecessary to output a clock signal as a reference from the semiconductor device CHP.

In FIG. 11, TSCC denotes a test circuit provided on the outside of the semiconductor device CHP. The test circuit TSCC is coupled to two output terminals of the semiconductor chip CHP. In the operation timing test, the test circuit TSCC obtains the time difference between changes in signals in the two output terminals and supplies it to a tester ATE. In FIG. 11, as an example, the test circuit TSCC is coupled to the output terminals Pol and Po2 of the semiconductor device CHP, and a signal according to the time difference between a change in the signal in the output terminal Pol and a change in the signal in the output terminal Po2 is supplied to the tester ATE synchronously with the test clock signal T-CLK. For example, in the operation timing test, when the selector MUX1 transmits the output signal IP1-1 to the output terminal Po1 and the selector MUX2 transmits the output signal IP1-n to the output terminal Po2 by the output path selection control signal generated by the output path test circuit TST-O, the test circuit TSCC generates a signal according to the time difference between the change in the signal in the output terminal Pol by the output signal IP1-1 and the change in the signal in the output terminal Po2 by the output signal IP1-n.

On the basis of the signal from the test circuit TSCC, the tester ATE determines whether the time difference is longer than predetermined time or not, and determines whether the operation timing test succeeds or fails.

The test circuit TSCC has a 2-input exclusive OR circuit ER and a pulse width measurement circuit TFC. One of inputs of the exclusive OR circuit ER is coupled to the output terminal Pol, and the other input is coupled to the output terminal Po2. With the configuration, in a period that the voltage of the signal in the output terminal Po1 and the voltage of the signal in the output terminal Po2 are different from each other, the exclusive OR circuit ER generates an output signal of the high level. In the period that the output signal of the exclusive OR circuit ER is at the high level, the pulse width measurement circuit TFC performs measurement by using a clock signal generated by a clock signal generation circuit PWG for pulse width measurement and outputs a signal synchronously with the test clock signal T-CLK. In such a manner, a signal corresponding to the period that the voltages of the output terminals Pol and Po2 are different from each other is supplied from the pulse width measurement circuit TFC to the tester ATE.

### Configuration of Output-Stage Test Circuit and Output-Stage F/F Circuit

Next, the configuration of the output-stage test circuit and the output-stage F/F circuit will be described with reference to FIG. 12. The output-stage test circuit TSO1-1 illustrated in FIG. 11 and the output-stage F/F circuit FFO1-1 corresponding to the output-stage test circuit TSO1-1 will be described as an example.

In FIG. 12, the output-stage F/F circuit FFO1-1 is a flip flop circuit having a reset terminal R, a data input terminal D, a data output terminal Q, a data inversion output terminal Q/, and a clock input terminal CK. The data inversion output terminal Q/ is a terminal of outputting an output signal obtained by inverting the logic of an output signal from the data output terminal Q.

When low level (logic value “0”) is supplied to the reset terminal R, the output-stage F/F circuit FFO1-1 enters a reset state, the data output terminal Q becomes the low level, and the data inversion output terminal Q/ becomes the high level (logic value “1”). When a signal supplied to the clock input terminal CK rises in a state where the reset terminal R is set at the high level, a signal supplied to the data input terminal D is fetched, the logic value of the fetched signal is held, and a signal corresponding to the held logic value is output from the data output terminal Q. A signal corresponding to the logic value obtained by inverting the logic value held is output to the data inversion output terminal Q/.

The output-stage test circuit TSO1-1 has selectors MUX8, MUX9, and MUX10. Each of the selectors MUX8 to MUX10 has an output terminal O1, input terminals N1 and N2, and a selection terminal S1, selects the input terminal N1 or N2 in accordance with the voltage of a signal supplied to the selection terminal S1, and couples the selected input terminal to the output terminal O1.

In the embodiment, the tester ATE generates the test control signal T-CTL including the test mode signal T-MOD and the reset pulse signal RST. The test mode signal T-MOD is a mode signal indicating, for example, the operation timing test or the normal operation (process mode).

The test mode signal T-MOD is supplied to the selection terminal S1 of each of the selectors MUX8 to MUX10. An output signal from the function unit IP1 is supplied to the input terminal N1 of the selector MUX8, the input terminal N2 is coupled to the data inversion output terminal Q/ of the output-stage F/F circuit FFO1-1, and the output terminal O1 is coupled to the data input terminal D of the output-stage F/F circuit FFO1-1. The internal operation clock signal OCLK is supplied to the input terminal N1 of the selector MUX9, the internal test clock signal TSCLK is supplied to the input terminal N2, and the output terminal O1 is coupled to the clock input terminal CK Of the output-stage F/F circuit FFO1-1 . A reset pulse signal RST is supplied to the input terminal N2 of the selector MUX10, and the output terminal O1 is coupled to the reset terminal R of the output-stage F/F circuit FFO1-1. Although not limited, the input terminal N1 of the selector MUX10 is coupled to, for example, high-level voltage. The data output terminal Q of the output-stage F/F circuit FFO1-1 is the output of the output-stage test circuit TSO1-1.

In the normal operation (process mode), the tester ATE sets the test mode signal T-MOD to the high level. In response to the high level, each of the selectors MUX8 to MUX10 selects the input terminal N1 and couples it to the output terminal O1. Since the input terminal N1 of the selector MUX8 is coupled to the output terminal O1, an output signal from the function unit IP1 is supplied to the data input terminal D of the output-stage F/F circuit FFO1-1. Since the input terminal N1 of the selector MUX9 is coupled to the output terminal O1, to the clock input terminal CK of the output-stage F/F circuit FFO1-1, the internal operation clock signal OCLK is supplied as a sync clock signal. Since the input terminal N1 is selected in the selector MUX10, the high-level signal is supplied to the reset terminal RST of the output-stage F/F circuit FFO1-1. As a result, when the internal operation clock signal OCLK changes, the output-stage F/F circuit FFO1-1 fetches an output signal from the function unit IP1 and outputs it from the data output terminal Q.

That is, in the normal operation, synchronously with the internal operation clock signal OCLK, an output signal from the function unit IP1 is fetched and is output as the output signal IP1-1 to the output path selection circuit ORSL.

At the time of executing the operation timing test, the tester ATE sets the test mode signal T-MOD to the low level. The tester ATE sets the reset pulse signal RST to the low level and, after that, sets it again to the high level. When the test mode signal T-MOD becomes the low level, each of the selectors MUX8 to MUX10 selects the input terminal N2 and couples the selected input terminal N2 to the output terminal O1.

Since the input terminal N2 of the selector MUX10 is coupled to the output terminal O1, the reset pulse signal RST is supplied to the reset terminal R of the output-stage F/F circuit FFO1-1. In the operation timing test, the tester ATE temporarily sets the reset pulse signal RST to the low level, the output-stage F/F circuit FFO1-1 enters a reset state. That is, an output signal of the low level is output from the data output terminal Q of the output-stage F/F circuit FFO1-1, and an output signal of the high level is output from the data inversion output terminal Q/. With respect to the remaining output-stage test circuits and output-stage F/F circuits, similarly, the output-stage F/F circuits are set to the reset state.

When the tester ATE sets the reset pulse signal RST to the high level again, since the input terminal N2 in each of the selectors MUX8 and MUX9 is selected, the internal test clock signal TSCLK is supplied as a sync clock signal to the clock input terminal CK of the output-stage F/F circuit FFO1-1, and an output signal from the data inversion output terminal Q/ is supplied to the data input terminal D. The output-stage F/F circuit FFO1-1 fetches an output signal of the high level output from the data inversion output terminal Q/ synchronously with the rising of the internal test clock signal TSCLK, outputs an output signal of the high level from the data output terminal Q, and outputs an output signal of the low level from the data inversion output terminal Q/. That is, the output-stage F/F circuit FFO1-1 fetches a signal obtained by inverting the logic value of the output signal output from the data output terminal Q synchronously with a change in the internal test clock signal TSCLK and outputs the inverted output signal from the data output terminal Q. Consequently, a signal whose logic value changes alternately synchronously with the internal test clock signal TSCLK is supplied as the output signal IP1-1 to the output path selection circuit ORSL.

Also in the remaining output-stage test circuits and output-stage F/F circuits, similarly, in the operation timing test, the signal whose logic value alternately changes synchronously with the internal test clock signal TSCLK is supplied as an output signal to the output path selection circuit ORSL.

FIG. 13 is a waveform chart illustrating operations in the case of using the output-stage test circuit and the output-stage F/F circuit depicted in FIG. 12 as the output-stage test circuits TSO1-1 to TSO1-n, TSO2-1 to TSO2-n, and TSO3-1 and the output-stage F/F circuits FFO1-1 to FFO1-n, FFO2-1 to FFO2-n, and FFO3-1 illustrated in FIG. 11. In FIG. 13, the horizontal axis indicates time. In FIG. 13, (A) indicates the waveform of the internal test clock signal TSCLK, (B) indicates changes in the voltage in the output terminal Po1, (C) indicates changes in the voltage in the output terminal Po2, and (D) indicates changes in the output of the exclusive OR circuit ER.

FIG. 13 illustrates the operations in the operation timing test and the case where, in the operation timing test, for example, an output path transmitting the output signal IP1-1 to the output terminal Po1 is formed and an output path transmitting the output signal IP1-n to the output terminal Po2 is formed by the output path test circuit TST-O.

In the operation timing test, as understood from the above description, the logic values held in the output-stage F/F circuits FFO1-1 and FFO1-n change alternately synchronously with the internal test clock signal TSCLK. Accordingly, the voltages of the output signals Po1 and Po2 also periodically change. For example, since the impedances of signal lines included in the output paths transmitting the output signals IP1-1 and IP1-n are different, as illustrated in (B) and (C) in FIG. 13, the rising timing and/or the trailing timing of the voltage in the output terminal Po1 are/is different from the rising timing and/or the trailing timing of the voltage in the output terminal Po2. Consequently, a period in which the voltages (logic values) in the output terminals Po1 and Po2 are different occurs. In this period, the exclusive OR circuit ER becomes the high level as illustrated in (D) in FIG. 13.

The period in which the output of the exclusive OR circuit ER is at the high level is converted to a count value by the pulse width measurement circuit TFC illustrated in FIG. 11 and the count value is transmitted to the tester ATE.

Since the output paths transmitting the output signals IP1-1 and IP1-n include not-illustrated signal lines, elements configuring selectors, and the like, changes in the voltages in the output terminals Pol and Po2 delay when the internal test clock signal TSCLK is used as a reference.

### First Modification

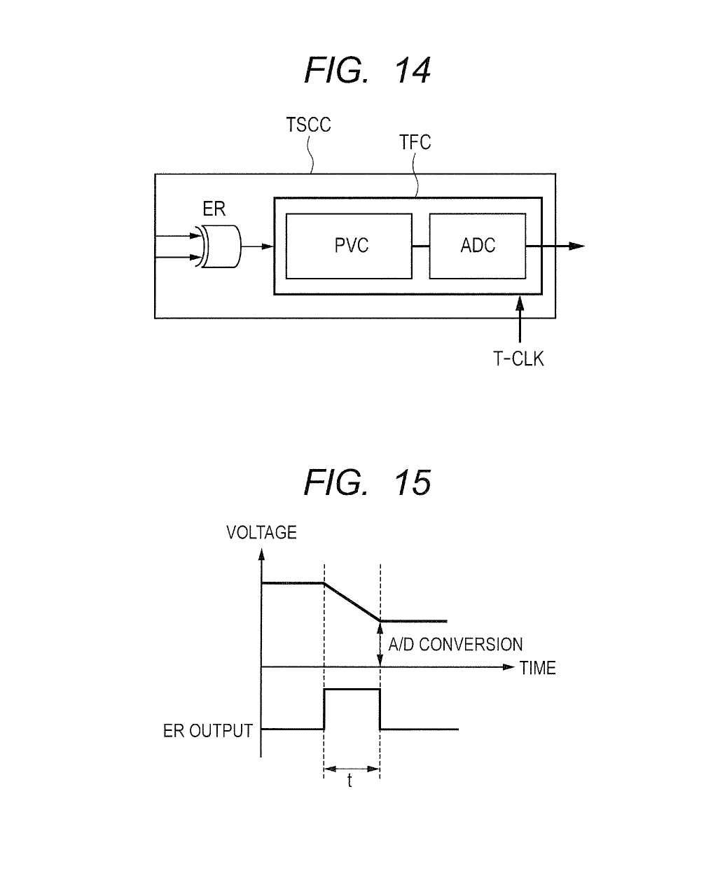

FIG. 14 is a block diagram illustrating the configuration of a modification of the test circuit TSCC. FIG. 15 is a waveform chart illustrating the operations of the test circuit TSCC depicted in FIG. 14. In the first modification, the pulse width measurement circuit TFC included in the test circuit TSCC illustrated in FIG. 11 is changed. That is, in the first modification, the pulse width measurement circuit TFC has a pulse width voltage conversion circuit PVC changing pulse width to voltage and an analog/digital (hereinbelow, also called A/D) conversion circuit ADC converting the voltage form the pulse width voltage conversion circuit PVC to a digital signal.

As described with reference to FIG. 11, in the operation timing test, the exclusive OR circuit ER outputs a high-level signal in a period that voltages (logic values) of the output terminals Po1 and Po2 are different. In the period that the output signal of the high level is output from the exclusive OR circuit ER, the pulse width voltage conversion circuit PVC outputs an output signal whose voltage value changes in an analog manner. For example, the pulse width voltage conversion circuit PVC can be a capacitance circuit configured by a capacitive element and a switch circuit. In this case, as illustrated in FIG. 15, when an output of the exclusive OR circuit ER is at the low level, the capacitive element is charged by the switch circuit. When an output of the exclusive OR circuit ER changes to the high level, discharging of charges in the capacitive element is started by the switch circuit, and the discharging is continued for a period “t” in which the output of the exclusive OR circuit ER is at the high level.

The A/D conversion circuit ADC converts, for example, at a timing when an output of the exclusive OR circuit ER changes to the low level, an output from the pulse width voltage conversion circuit PVC, that is, the voltage from the capacitance circuit to a digital signal. Consequently, the digital signal corresponding to the time of difference between the voltages (logic values) between the output terminals Pol and Pot can be supplied from the A/D conversion circuit ADC to the tester ATE.

In the first modification, the A/D conversion circuit ADC is synchronized with the test clock signal T-CLK so that the A/D conversion circuit ADC can start A/D conversion at a proper timing.

Although the example that the capacitive element A/D converts the discharged voltage in the period “t” has been described as the first modification, in the period “t”, the capacitive element may be charged and the charged voltage may be A/D converted.

### Second Modification

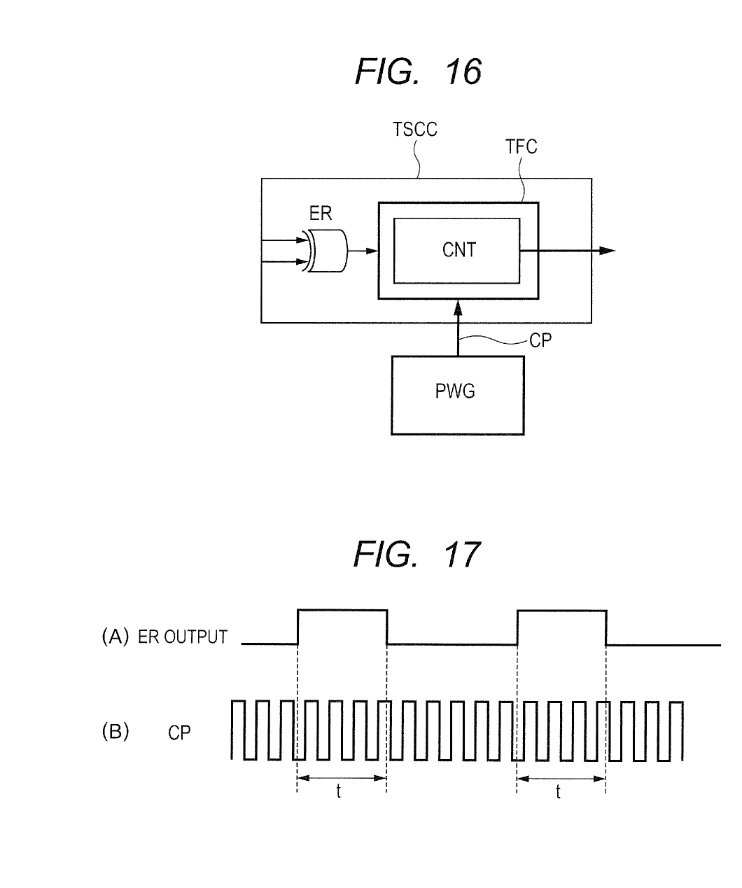

FIG. 16 is a block diagram illustrating the configuration of a modification of the test circuit TSCC. FIG. 17 is a waveform chart illustrating the operations of the test circuit TSCC depicted in FIG. 16. In a second modification, the pulse width measurement circuit TFC included in the test circuit TSCC illustrated in FIG. 11 is changed. That is, in the second modification, the pulse width measurement circuit TFC has a counter CNT counting a clock signal CP generated by the clock signal generation circuit PWG for pulse width measurement.

In FIG. 17, the horizontal axis indicates time. (A) in FIG. 17 indicates the waveform of the exclusive OR circuit ER, and (B) in FIG. 17 indicates the waveform of the clock signal CP generated by the clock signal generation circuit PWG for pulse width measurement. The period in which the exclusive OR circuit ER is at the high level is, for example, 30 ns. The clock signal of a frequency generated by the clock signal generation circuit PWG for pulse width measurement is set so that the cycle of the clock signal is sufficiently shorter than the period in which the output of the exclusive OR circuit ER is at the high level.

The counter CNT counts the number of the clock signals CP during the period in which the output of the exclusive OR circuit ER is at the high level. A count value obtained by the counting is supplied to the tester ATE.

As the third embodiment and is modification, the example of using the exclusive OR circuit ER as the test circuit TSCC has been described but the invention is not limited to the example. Without using the exclusive OR circuit ER, for example, a counter may be provided which sets a voltage change in the output terminal Po1 as a start signal and uses a voltage change in the output terminal Po2 as a stop signal. In this case, it is sufficient to supply a count value from the start to stop of the counter to the tester ATE.

In the third embodiment, a change in a signal occurs in each of two or more output terminals synchronously with the test clock signal T-CLK. Determination of the operation timing test is performed on the basis of the time difference of the signal changes between the output terminals. The time difference of the signal changes between the output terminals does not depend on the frequency of the test clock signal T-CLK. Specifically, an example of using the exclusive OR circuit ER in the test circuit TSCC will be described. A period in which an output of the exclusive OR circuit ER is at the high level does not depend on the frequency of the test clock signal T-CLK, and a period in which the output is at the low level changes according to the frequency (depends on the frequency).

Although the timing the period in which the output of the exclusive OR circuit ER becomes the high level occurs in the cycle of the test clock signal T-CLK is unknown, the period occurs in the cycle of the test clock signal T-CLK. Consequently, by comparing a digital value output from the test circuit TSCC with the expectation value synchronously with the test clock signal T-CLK, a result of the operation timing test can be obtained.

Since the period of the high level output from the exclusive OR circuit ER does not depend on the frequency of the test clock signal T-CLK, for example, an operation timing test can be also carried out while lowering the frequency of the test clock signal T-CLK and reducing power consumption.

In the third embodiment, the example of providing the test circuit TSCC on the outside of the semiconductor device CHP and the tester ATE has been described. However, the invention is not limited to the example. The test circuit TSCC may be provided in the semiconductor device CHP or in the tester ATE.

In the first to third embodiments, the function test on the process units such as the processor CPU (user circuit) and the operation timing test are separated. Consequently, when the operation timing test is execute, the function test on the process unit may not be executed. It can reduce power consumption of the semiconductor device in the operation timing test. In the test process in the process of manufacturing the semiconductor device, a number of semiconductor devices are operated substantially at the same time. Consequently, by reducing the power consumption of the semiconductor device in a test, the size of a power supply used in the test process can be also reduced.

In the first to third embodiments, the test pattern used for the operation timing test is supplied from the tester or the like to the semiconductor device without operating the process unit such as the processor CPU provided in the semiconductor device. Consequently, it is unnecessary to generate a program for a test adapted to the processor CPU for the operation timing test, and time required for a test can be shortened. For example, in the case of generating a program for a test and executing the operation timing test, for example, a failure is determined in the operation timing test, to assure that the cause of the failure is not due to the program for the test, sufficient verification of the program for the test is required, and time required for the test becomes long. Without grasping the functions of the processor CPU and the like, a test pattern for the operation timing test can be generated, and time required for the test can be shortened.

Further, since an input path between an input terminal and an input-stage F/F circuit is determine by the input path test circuit, the relation between a test pattern supplied to the input terminal and a pattern stored in the input-stage F/F circuit can be arbitrarily determined. Since an output path between an output-stage F/F circuit and an output terminal is determined by an output path test circuit, the relation between a test pattern stored in the output-stage F/F circuit and a pattern in the output terminal can be arbitrarily determined.

In the semiconductor device CHP, a number of F/F circuits are provided. It is difficult to adjust synchronization timings in all of the F/F circuits provided in the semiconductor device CHP. The ratio of the input-stage F/F circuits and the output-stage F/F circuits in the number of all of F/F circuits provided in the semiconductor device CHP is about less than 1%. It is relatively easy to adjust synchronization timings among the input-stage F/F circuits or the output-stage F/F circuits, so that timing design or timing management of the semiconductor device CHP is facilitated.

### Supplemental Notes

A plurality of inventions are disclosed in the specification. Some of them are described in the scope of claims for patent. Inventions other than those invention are also disclosed and representative inventions will be described as follows.
(A) A method of manufacturing a semiconductor device, including a manufacturing step of manufacturing a semiconductor device and a testing step of testing a semiconductor device manufactured in the manufacturing step by using a test circuit, the semiconductor device including:

a first external terminal to which an operation clock signal is supplied;

a second external terminal to which a test clock signal is supplied in the testing step;

a process unit including a logic circuit and a plurality of flip flop circuits each operating synchronously with the operation clock signal and generating first and second output signals;

third and fourth external terminals, when the process unit generates the first and second output signals, to which the first and second output signals are transmitted;

a first output-stage flip flop circuit coupled between the process unit and the third external terminal;

a second output-stage flip flop circuit coupled between the process unit and the fourth external terminal;

a first selection circuit coupled to the first output-stage flip flop circuit and selecting a sync signal with which the first out-stage flip flop circuit is synchronized and an input of the first output-stage flip flop circuit; and

a second selection circuit coupled to the second output-stage flip flop circuit and selecting a sync signal with which the second output-stage flip flop circuit is synchronized and an input of the second output-stage flip flop circuit,

wherein when the process unit generates the first and second output signals, the first and second selection circuits select the operation clock as the sync clock signal and select the first and second output signals as inputs of the first and second output-stage flip flop circuits,

in the testing step, the first and second selection circuits select the test clock signal as the sync clock signal and select the outputs of the first and second output-stage flip flop circuits as inputs of the first and second output-stage flip flop circuits so that outputs of the first and second output-stage flip flop circuits change synchronously with the test clock signal, and

the test circuit is coupled between the third and fourth external terminals and, in the testing step, obtains the time difference between a change in a signal in the third external terminal and a change in a signal in the fourth external terminal.
(B) In the method of manufacturing a semiconductor device described in (A), the test circuit operates synchronously with the test clock signal.
(C) In the method of manufacturing a semiconductor device described in (B), the test circuit has:

a logic circuit coupled to the third and fourth external terminals and, in the testing step, outputting a detection signal when voltage of a signal in the third external terminal and voltage of a signal in the fourth external terminal are different from each other;

a capacitance circuit releasing charges in response to a detection signal from the logic circuit; and

an analog/digital conversion circuit converting an output signal of the capacitance circuit changing according to the release of charges.
(D) In the method of manufacturing a semiconductor device described in (C), the analog/digital conversion circuit converts an output signal of the capacitance circuit to a digital signal synchronously with the test clock signal.

The present invention achieved by the inventors herein has been concretely described above on the basis of the embodiments. Obviously, the present invention is not limited to the embodiments and can be variously changed without departing from the gist.

What is claimed is:

1. A semiconductor device comprising:
a first external terminal to which an operation clock signal is supplied;
a process unit including a logic circuit and a plurality of flip flop circuits each operating synchronously with the operation clock signal;
a second external terminal to which an output signal generated by the process unit is transmitted;
an output-stage flip flop circuit coupled between the process unit and the second external terminal;
a third external terminal to which a test signal is supplied;
a fourth external terminal to which a test clock signal is supplied;
a fifth external terminal to which the test clock signal is transmitted via a signal line; and
a first selection circuit selecting a clock signal with which the output-stage flip flop circuit is synchronized and an input of the output-stage flip flop circuit,
wherein the first selection circuit, at the time of transmitting an output signal generated by the process unit to the second external terminal, inputting the output signal to the output-stage flip flop circuit and supplying the operation clock signal as a sync clock signal and, at the time of a test, inputting the test signal to the output-stage flip flop circuit and supplying the test clock signal as a sync clock signal.

2. The semiconductor device according to claim 1,
wherein the semiconductor device comprises a plurality of second external terminals, a plurality of output-stage flip fop circuits, and a plurality of first selection circuits, and
wherein the semiconductor device further comprises:
an output path selection circuit coupled between the output-stage flip flop circuits and the second external terminals, and forming a coupling path between each of the output-stage flip flop circuits and each of the second external terminals in accordance with an output path selection signal; and
a second selection circuit generating the output path selection signal at the time of a test.

3. The semiconductor device according to claim 2, further comprising a sixth external terminal to which a signal is supplied at the time of a test,
wherein the second selection circuit generates the output path selection signal in accordance with the signal supplied to the sixth external terminal.

4. The semiconductor device according to claim 3, wherein at the time of a test, each of the first selection circuits selects, as an input, an output of an output-stage flip flop circuit of a front stage which is coupled to a corresponding output-stage flip flop circuit in series so that the output-stage flip flop circuits are coupled in series.

5. The semiconductor device according to claim 4, further comprising:
a plurality of seventh external terminals to each of which an input signal is supplied;
a plurality of input-stage flip flop circuits coupled between the seventh external terminals and the process unit;
an eighth external terminal to which outputs of the input-stage flip flop circuits are transmitted;
a third selection circuit selecting a clock signal with which the input-stage flip flop circuits are synchronized;
an input path selection circuit coupled between the input-stage flip flop circuits and the seventh external terminals and forming a coupling path between each of the input-stage flip flop circuits and each of the seventh external terminals in accordance with an input path selection signal; and
a fourth selection circuit generating the input path selection signal at the time of a test,
wherein the third selection circuit selects, when the process unit processes the input signals, the operation clock signal as a sync clock signal of the input-stage flip flop circuits and selects, at the time of a test, the test clock signal as a sync clock signal of the input-stage flip flop circuits, and the fourth selection circuit generates the input path selection signal in accordance with a signal supplied to the sixth external terminal.

6. The semiconductor device according to claim 5,
wherein the semiconductor device has a process mode in which the process unit operates and a test mode, and
wherein in the test mode, at least one of the first selection circuit and the third selection circuit operates.

7. A semiconductor device comprising:
a first external terminal to which an operation clock signal is supplied;
a second external terminal to which an input signal is supplied;
a process unit including a logic circuit and a plurality of flip flop circuits each operating synchronously with the operation clock signal;
a third external terminal to which a test clock signal is supplied;
an input-stage flip flop circuit coupled between the second external terminal and the process unit;
a fourth external terminal to which an output of the input-stage flip flop circuit is transmitted; and
a first selection circuit selecting a clock signal with which the input-stage flip flop circuit is synchronized,
wherein the first selection circuit selects, when the process unit processes the input signal, the operation clock signal as a sync clock signal of the input-stage flip flop circuit and selects, at the time of a test, the test clock signal as a sync clock signal of the input-stage flip flop circuit.

8. The semiconductor device according to claim 7,
wherein the semiconductor device comprises a plurality of second external terminals, a plurality of input-stage flip fop circuits, and a plurality of first selection circuits, and
wherein the semiconductor device further comprises:
an input path selection circuit coupled between the second external terminals and the input-stage flip flop circuits, and forming a coupling path between each of the second external terminals and each of the input-stage flip flop circuits; and
a second selection circuit generating the input path selection signal at the time of a test.

9. The semiconductor device according to claim 8,
wherein when an output of the input-stage flip flop circuit is transmitted to the fourth external terminal, the first selection circuit selects an output of an input-stage flip flop circuit of a front stage coupled in series as an input of a corresponding input-stage flip flop circuit so that the input-stage flip flop circuits are coupled in series.

10. A semiconductor device comprising:
a first external terminal to which an operation clock signal is supplied;
a second external terminal to which a test clock signal is supplied;
a process unit including a logic circuit and a plurality of flip flop circuits each operating synchronously with the operation clock signal, and generating a first output signal and a second output signal;
third and fourth external terminals, when the process unit generates the first and second output signals, to which the first and second output signals are transmitted;
a first output-stage flip flop circuit coupled between the process unit and the third external terminal;
a second output-stage flip flop circuit coupled between the process unit and the fourth external terminal;
a first selection circuit coupled to the first output-stage flip flop circuit and selecting a sync clock signal with which the first output-stage flip flop circuit is synchronized and an input of the first output-stage flip flop circuit; and
a second selection circuit coupled to the second output-stage flip flop circuit and selecting a sync clock signal with which the second output-stage flip flop circuit is synchronized and an input of the second output-stage flip flop circuit,
wherein the first and second selection circuits select, when the process unit generates the first and second output signals, the operation clock signal as the sync clock signal and select the first and second output signals as inputs of the first and second output-stage flip flop circuits, and
wherein at the time of a test, the first and second selection circuits select the test clock signal as the sync clock signal and select outputs of the first and second output-stage flip flop circuits as inputs of the first and second output-stage flip flop circuits so that the outputs of the first and second output-stage flip flop circuits change synchronously with the test clock signal.

11. The semiconductor device according to claim 10, further comprising a test circuit coupled between the third and fourth external terminals and, at the time of a test, outputting a value according to a time difference between a change in a signal in the third external terminal and a change in a signal in the fourth external terminal.

12. The semiconductor device according to claim 11,
wherein the test circuit comprises a capacitance circuit and an analog/digital conversion circuit converting an output of the capacitance circuit to a digital signal,
wherein an output of the capacitance circuit changes due to discharge during a period in which a signal in the third external terminal and a signal in the fourth external terminal are different from each other.

13. The semiconductor device according to claim 11,
wherein the test circuit comprises a counter circuit, and
wherein counting operation is performed by the counter circuit in a period in which a signal in the third external terminal and a signal in the fourth external terminal are different from each other.
